(19) United States
(12) Patent Application Publication
(10) Pub. No.: US 2020/0313049 A1
(43) Pub. Date: Oct. 1, 2020

(54) LIGHT EMITTING DIODE PACKAGE

(71) Applicant: Soraa, Inc., Fremont, CA (US)

(72) Inventors: Kevin HUANG, Fremont, CA (US); Aurelien J.F. DAVID, Fremont, CA (US); Stefan EBERLE, Fremont, CA (US); Rohit MODI, Fremont, CA (US); Scott WEST, Fremont, CA (US); Michael J. CICH, Fremont, CA (US); Rafael I. ALDAZ, Fremont, CA (US); Michael D. CRAVEN, Fremont, CA (US)

(21) Appl. No.: 16/312,470

(22) PCT Filed: Jun. 21, 2017
(86) PCT No.: PCT/US17/38625

§ 371 Date: Dec. 21, 2018

Related U.S. Application Data
(60) Provisional application No. 62/352,864, filed on Jun. 21, 2016.

(51) Int. Cl. H01L 33/54; H01L 33/62; H01L 33/46; H01L 33/60; H01L 33/48

(52) U.S. Cl. CPC H01L 33/54; H01L 33/62; H01L 33/486; H01L 33/60; H01L 33/46

(57) ABSTRACT

In one embodiment, the LED package comprises: (a) a submount comprising a substrate, at least one electrical interface, and a non-conductive reflective material disposed over substantially all of submount except for the at least one electrical interface; and (b) an LED chip having sides and at least one contact, the LED chip being flip-chip mounted to the submount such that the at least one contact is electrically connected to the at least one electrical interface, the LED chip covering a substantial portion of the at least one electrical interface, substantially all of the chip extending above the reflective material.

### RELATED APPLICATION

This application is based on U.S. Provisional Application No. 62/352,864, filed Jun. 21, 2016, hereby incorporated by reference in its entirety.

### FIELD OF INVENTION

The present invention relates, generally, to a package, and, more specifically, to a light emitting diode (LED) package suitable for shorter-wavelength LEDs.

### BACKGROUND

Conventional mid-power packages (MPP) use leadframe architecture with a wire-bonded die and exposed silver for high optical reflectivity. Typically, blue pump LEDs are employed and are encapsulated in a phenyl-based silicone. Such silicones have a rather high index (˜1.5) and tend to protect the silver against corrosion/tarnishing.

Although such MPPs may be sufficient for blue, wire-bonded LEDs, Applicants have identified a number of shortcomings of such packages for shorter wavelength LEDs and for flip-chip packages. (As used herein short-wavelength light comprises light at a wavelength significantly shorter than standard blue LEDs, for instance a peak wavelength below 430 nm, below 420 nm, or in one of the following ranges: 200-400 nm, 200-430 nm, 300-400 nm, 300-430 nm, 360-400 nm, 360-430 nm, 380-400 nm, 380-420 nm, 380-430 nm, 400-420 nm, 400-430 nm, 400-440 nm.)

First, Applicants recognize that typical leadframe packages have components with disparate thermal expansion coefficients, which tend to stress flip-chip connections. Specifically, the leadframe core is made of metal, such as copper, which has a thermal expansion coefficient much higher than that of the semiconductor material of the chip. In the case of a flip chip, the chip's electrical contacts are connected directly to the leadframe, as opposed to a wire bond in which the chip is connected to the leadframe through a relatively flexible wire. Thus, in flip-chip configurations, the direct connection between the chip's contacts and the leadframe undergo significant stress as the package thermally cycles. This stress may compromise not only the reliability of the chip's connection, but also the chip itself.

Second, the phenyl silicones often used for encapsulating the chip and securing it to the leadframe tend to be problematic at shorter wavelengths Specifically, phenyl silicone tends to absorb shorter wavelengths (e.g., violet light), causing it to become cloudy and thus diminish the optical performance of the LED package, eventually causing reliability failures. While other silicones, such as methyl silicones, may be more transparent at shorter wavelengths, they tend to be ineffective barriers to protect silver, allowing the silver to tarnish and lose its reflectivity over time.

Third, traditional manufacturing techniques for leadframes tend to be too “coarse” for smaller LED chips. Specifically, leadframes typically are produced using wet etching. Achieving small gaps between electrical pads using wet etching is difficult to do. This in turn, limits the smallest possible spacing between electrodes in a flip-chip device. However, it is sometimes desirable to make the LED chips as small as possible.

In view of these limitations, Applicants have identified the need for a robust LED package architecture that can accommodate flip-chip, shorter-wavelength LEDs with high reliability and optical performance. The present invention fulfills this need among others.

### SUMMARY OF INVENTION

The following presents a simplified summary of the invention in order to provide a basic understanding of some aspects of the invention. This summary is not an extensive overview of the invention. It is not intended to identify key/critical elements of the invention or to delineate the scope of the invention. Its sole purpose is to present some concepts of the invention in a simplified form as a prelude to the more detailed description that is presented later.

The present invention involves, in one embodiment, using a dimensionally-stable substrate with a flip-chip LED and a reflective coating to minimize exposure of electrical conductors in the package. Specifically, Applicants have discovered that by using a substrate material, such as a ceramic, that is dimensionally stable through a wide range of temperatures for the bulk of the submount, the thermal expansion differences in the package can be minimized, thereby facilitating a more robust bond between the LED chip and the pads on the submount.

Additionally, Applicants have discovered that, while a flip-chip configuration presents certain challenges in connection with the integrity of the electrical connections between the submount and the LED chip as discussed above, it also provides some unexpected benefits. For example, because the chip is upside down, it essentially covers the electrical interface with the submount, which is often a point of diminished reflectivity in the LED package. A flip-chip architecture also provides excellent heatsinking for the LED.

In one configuration, the present invention provides for a package in which relatively small pads are provided on the surface of the submount to effect an electrical coupling between the LED chip and the electrically-conductive traces in the submount. The small pads are concealed by the flipped chip. Because the electrical connection between the traces and the LED chip is through the pads, the rest of the traces can be covered/concealed by a material which is reflective, but not necessarily conductive. In other words, in one embodiment, there is no need to coat the traces with a material, such as silver, which is used to enhance the traces' reflectivity without diminishing conductivity. (As mentioned above, materials such as silver, which are conductive and reflective, are not only expensive, but also tend to tarnish and diminish performance, especially if certain silicon encapsulants are used because of a violet LED.) Accordingly, Applicants have developed a configuration in which the LED packaging has essentially no exposed traces which would otherwise diminish the package's reflectivity.

In another embodiment, traces are coated with a material, such as silver, which provides reflectivity and conductivity, but the material is coated with barrier to protect the material from corrosion while not diminishing its reflectiveness. Again, a package configuration is provided in which the LED packaging has essentially no exposed traces, which would otherwise diminish the package's reflectivity.

In one embodiment, an LED package is disclosed having a flip chip and a reflective layer, which cover the traces on a non-conductive submount. In another embodiment, an LED package is disclosed having relatively small pads to connect the LED chip to the submount and a reflective layer otherwise covering the traces. In one embodiment, the LED package comprises: (a) a submount comprising a substrate, at least one electrically-conductive trace disposed on the submount, and at least one pad disposed on a first portion of the at least one electrically-conductive trace, thereby defining a second portion of the at least one electrically-conductive trace on which the at least one pad is not disposed, the first portion having an area smaller than that of the second portion, and a non-conductive reflective material disposed over substantially all of the second portion; and (b) an LED chip being flip-chip mounted to the submount such that the at least one contact is electrically connected to the at least one pad, the LED chip covering a substantial portion of the at least one pad.

In yet another embodiment, a method is disclosed of making a LED package having relatively small pads to connect the LED chip to the submount and a reflective layer otherwise covering the traces. In one embodiment, the method comprises: (a) depositing two or more traces on an insulting substrate; (b) depositing at least one pad on a portion of each trace; (c) depositing a non-conductive reflective material such that it covers the substrate and traces but not the pads; and (d) after depositing the reflective material, flip chip mounting the LED chip to two of the pads.

In still another embodiment, an LED package is disclosed having a flip chip connected to a conductor, which is covered by a conductive and reflective material, which is further coated with a barrier layer to prevent corrosion. In one embodiment, the LED package comprises: (a) a substrate; (b) at least one electrical conductor disposed on the substrate; (c) a reflective material disposed over a major portion of the at least one electrical conductor; (d) a protective layer disposed over a portion of the reflective material; and (e) a violet LED chip having at least one contact, the at least one contact being electrically connected to the at least one electrical conductor through the reflective layer.

In yet another embodiment, an LED package is disclosed having a compliant die attach to accommodate differences in the thermal expansion of the components of the package. In one embodiment, the LED package comprises: (a) a submount having an electrical interface; (b) a LED chip connected to the electrical interface; and (c) a die connect between the LED chip and the submount, the die connect comprising at least one layer of Sn having a thickness of at least 5 um.

### BRIEF DESCRIPTION OF FIGURES

FIG. 1 shows a cross section side view of one embodiment of the LED package of the present invention.

FIG. 2 shows a top view of the LED package embodiment of FIG. 1.

FIG. 3 shows a cross section side view of alternative embodiment of the LED package of the present invention.

FIGS. 4(a-d) compares different embodiments of the LED package of the present invention (FIGS. 4(a) and (b)) with prior art LED packages (Figs (c) and (d)).

FIGS. 5(a) and (b) are side views of alternative embodiments of the LED package of the present invention.

FIG. 6 shows another embodiment of the LED package of the present invention.

FIG. 7 shows another embodiment of the LED package of the present invention.

FIGS. 8(a)-(c) show process steps of preparing one embodiment of the LED package of the present invention.

FIGS. 9 (a)-(d) show process steps of making the LED package of FIG. 1.

FIG. 10 shows experimental evidence of packaged light output vs package size.

FIG. 11(a) shows the reflectivity of different material configurations, and FIG. 11(b) shows reflectivity of cup material.

FIG. 12 shows the color uniformity of the LED package of the present invention.

FIG. 13(a) shows a microscope imaging of a die having a crack in the p-metal stack, in contrast to FIG. 13(b) which shows that the Sn die attach of the present invention showed no such defect because of its better compliance.

FIG. 14 shows the reflectivity of different configurations of white material on different surfaces

FIG. 15 shows an embodiment of the metal stack.

FIG. 16 shows a flip-chip die having a contact redistribution scheme.

FIG. 17 illustrates an LED package according at least one embodiment of the invention.

FIGS. 18 and 19 illustrate various implementation of a protective coating according to various embodiments of the invention.

FIG. 20 illustrates a multilayer protective coating according to an embodiment of the invention.

FIG. 21 shows a graph of the reflectively of a protective coating according to an embodiment of the invention.

FIG. 22 shows a graph of the transmission percentage of a protective coating according to an embodiment of the invention.

FIG. 23 shows a graph of the radiometric degradation of various types of LED packages according to embodiments of the invention.

FIG. 24 shows a graph of the radiometric degradation of an LED package in the presence of different wavelengths of emitted light according to embodiments of the invention.

FIG. 26 shows a graph of the radiometric degradation of LED packages according to embodiments of the invention.

FIG. 27 shows images of two families of mid-power packages according to embodiments of the invention.

FIG. 28 shows images of packages exposed to an atmospheric agent according to embodiments of the invention.

FIG. 29 illustrates a comparison of wet high temperature operating life reliability of LED packages according to embodiments of the invention.

### DETAILED DESCRIPTION

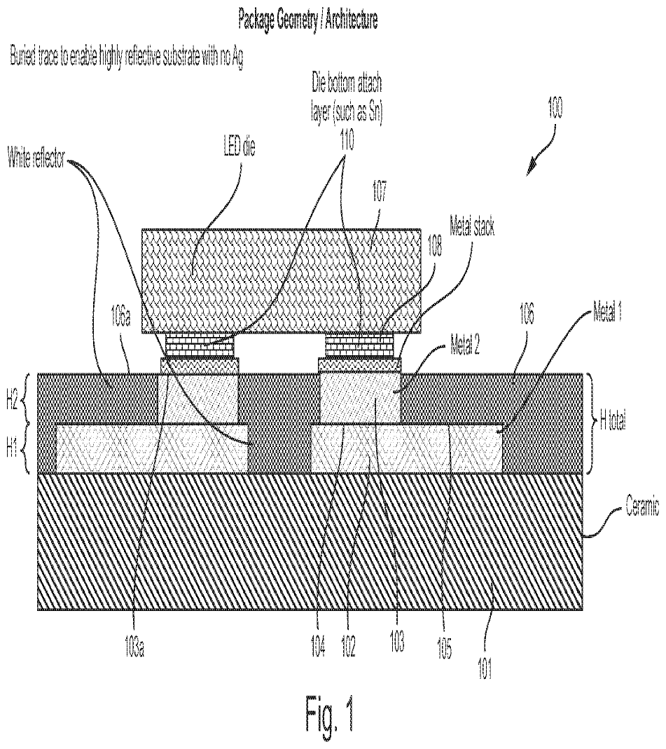

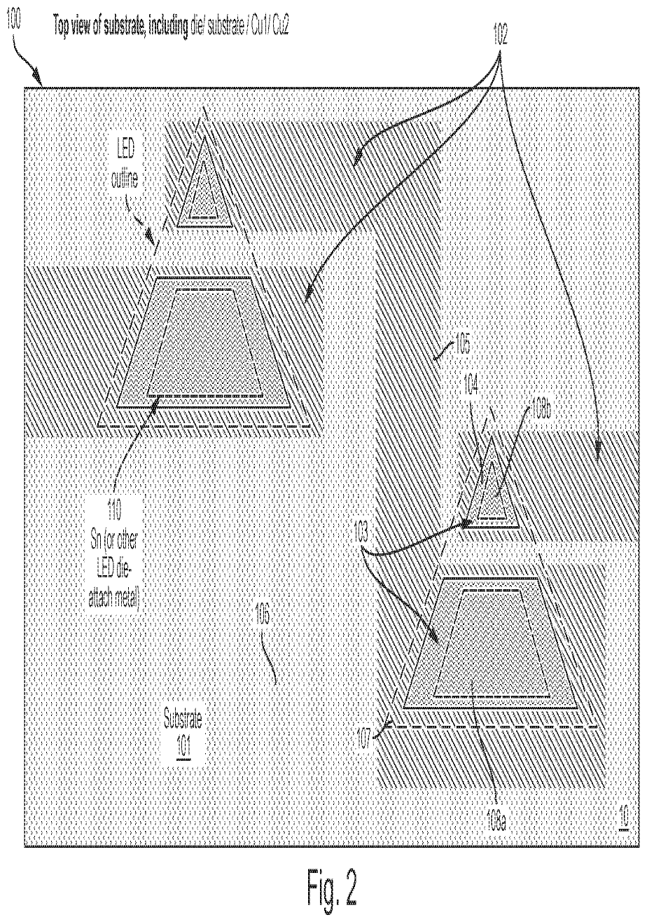

Referring to FIG. 1, one embodiment of an LED package 100 of the present invention is shown. The package 100 comprises a submount 150 comprising a substrate 101, at least one electrical interface 160, and a non-conductive reflective material 106 disposed over substantially all of the submount except for the at least one electrical interface. The package also comprises an LED chip 107 having sides 120 and at least one contact 108. The LED chip is flip-chip mounted to the submount such that the at least one contact is electrically connected to the at least one electrical interface. When mounted, the LED chip covers a substantial portion of the at least one electrical interface, and substantially all of the chip extends above the reflective material. The elements/features of this embodiment are described in greater detail below.

An important feature of this embodiment is that the area of the electrical interface 160 on the surface of the submount 150 is relatively small, thereby allowing the rest of the submount to be covered by the reflective material 106. Furthermore, because the electrical interface area is relatively small, it can be readily covered by the chip to minimize the non-reflective portions of the package. By disposing the reflective material over substantially all of the chip except for the electrical interface, and by disposing the chip over a substantial portion of the electrical interface, the electrical conductors of the submount, which may have poor reflectively, are not exposed. In one embodiment, substantially all is at least 75%, in another embodiment, at least 90%, and, in another embodiment, at least 99%. In one embodiment, the substantial portion is at least 75%, and, in a more particular embodiment, the substantial portion is at least 90%. In one embodiment, the area of the electrical interface is no more than 20% of the top surface area of the package, in another embodiment, no more than 10%, and, in yet another embodiment, no more than 5%. It should be understood that the packages described herein may further comprise a phosphor material. The phosphor material may be disposed around the LED die, and may cover a fraction of the package or substantially all the package. In the present discussion, the “top surface” of the package refers to the surface before the phosphor material is dispensed.

The electrical interface 160 may vary in configuration. Referring to FIG. 1, in one particular embodiment, the electrical interface comprises an electrically-conductive trace 102 disposed on the substrate and at least one pad 103 disposed on a first portion 104 of the at least one electrically-conductive trace, thereby defining a second portion 105 of the at least one electrically-conductive trace on which the at least one pad is not disposed. The first portion 104 has an area smaller than that of the second portion 105. (As used in this context, area refers to the top surface of the trace.) In one embodiment, the first portion is no more than 75% of the second portion, in another embodiment, no more than 50%, in yet another embodiment, no more than 25%, and, in a more particular embodiment, the first portion is no more than 10% of the second portion. The reflective layer 106 is disposed over substantially all of the second portion. The LED chip 107 is electrically connected to the at least one pad 103. This attach is usually achieved by attaching the die's metal stack 108 to the submount's metal stack 110. As mentioned above, the chip covers a substantial portion of the at least one pad (from a top perspective).

Referring to FIG. 2, a top view of the embodiment of FIG. 1 is shown. As mentioned above, an important feature of this embodiment is that the electrical connection between the chip 107 and traces 102 is through relatively small pads 103 overlaying a small first portion 104 of the traces 102, thereby allowing the rest of the traces (i.e., the second portion 105) to be covered by a reflective layer 106. This is an important feature because only the pads are exposed on the package's top surface. Furthermore, because the pads are relatively small they can be readily covered by the chip as described above to minimize the non-reflective portions of the package. In one embodiment, the area of the pads is no more than 20% of the top surface area of the package, in another embodiment, no more than 10%, and in yet another embodiment, no more than 5%.

Because the pads 103 and traces 102 are not exposed in the package, they need not be reflective. Instead, the first and second materials used for these traces and pads, respectively, may be optimize for a particular application/objective—e.g., electrical conduction, thermal expansion, cost, etc. Likewise, the material used in the pads may be different than the material used in the trace, allowing each material to be optimize for a particular application/objective. In one embodiment, the first and second metals have a higher conductivity and a lower reflectivity than silver. In one embodiment, the material for the pads and traces is optimize for conductivity. In one embodiment, the material is cooper. The dimensions of traces 102 may be selected to ensure low resistance. In particular, the cross-section of the traces may be sufficient to cause low resistance. In some embodiments, the total resistance of the package traces is less than 10 Ohm, 5 Ohm, 1 Ohm, 0.5 Ohm, 0.1 Ohm, 0.05 Ohm, 0.01 Ohm. In some embodiments, the cross-section of the traces has an area of at least 10×10 um or 20×20 um or 30×30 um or 40×40 um or 50×50 um. Furthermore this cross-section need not be square. The traces may have a width larger than their height, such that the traces are thin enough and can be easily covered with reflective material. In some embodiments, the thickness of the traces on top of the substrate is less than 50 um, 30 um, 20 um, 10 um. In one embodiment, the material for the traces and pads is nonetheless coated with a reflective material like silver (for instance, the trace sidewalls are made reflective such that light diffusing to these sidewalls is not lost); and the reflective material overlying the traces may act as a barrier for silver tarnishing. This freedom to select a trace cross-section for low resistance distinguishes embodiments from prior art having exposed metal traces (in which case, there may be an incentive to minimize the cross-section to limit losses)

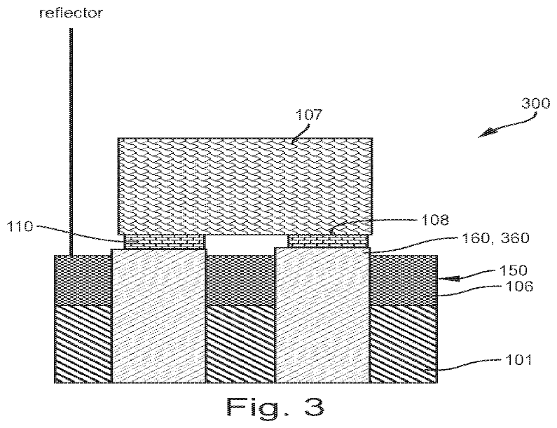

Referring to FIG. 3, another embodiment of the electrical interface 160 is shown. Here, the electrical interface 160 is part of a via 360, which extends through the submount to the bottom of the substrate 101. Like the pads described above, the via exposes a relatively small surface area on the submount which is readily covered by the chip. Vias and traces may further be combined. For instance, the traces of FIGS. 1-2 may be connected to vias elsewhere in the package, to enable surface mount of the package.

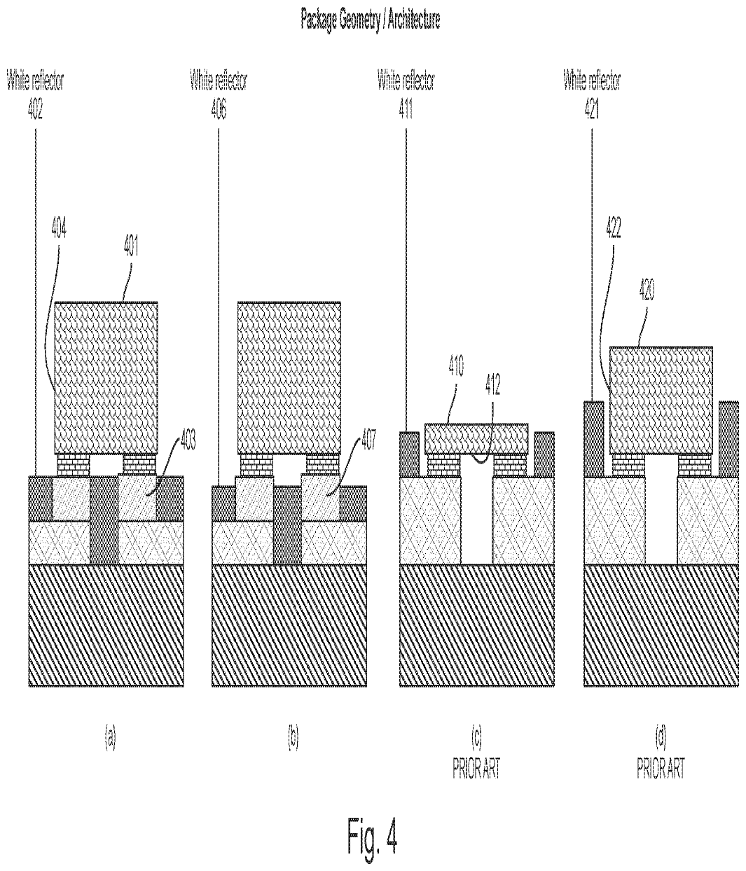

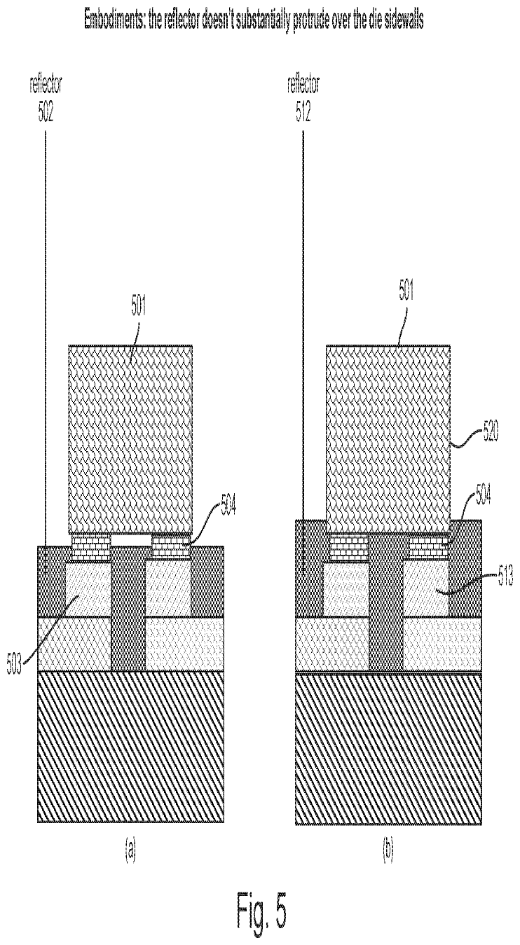

Another feature of this embodiment is that substantially all of the chip extends above the reflective material. This is an important feature, especially for volumetric LED chips. In volumetric flip-chip embodiments, the substrate of the chip faces upward (above the die epi), and light is emitted from the chip's sides. (Volumetric chips are described in greater detail below.) For this reason, in one embodiment, the sides of the chip extend above the reflective material. This is illustrated in FIG. 4, which compares various configurations (a-d), and contrasts embodiments in which the die walls are substantially above the reflective material (a and b), to those in which the walls are not substantially above the reflective material (c and d) FIG. 4(a) shows a volumetric die 401 with a white reflector 402 flush with the electrical interface 403. The surface reflector may be printed on top of the package then lapped/polished back to a desired thickness. In some cases the polishing ensures that the surface reflector and one of the metal layers are flush (for instance, they are planar within +/−10 um or 5 um or 2 um). In this case, light emitted from the die sides 404 can escape. This is important since a large fraction of the light (e.g., more than 10%, 20%, 30%, 40% or 50%) may be emitted from the sides of a volumetric die. FIG. 4(b) shows a similar embodiment in which the white material 406 is nearly flush with the electrical interface 407 (it might be a bit above or below the metal, but does not extend substantially above the bottom of die side). Here again, light emitted from the die sides can escape.

FIG. 4(c) shows a more standard configuration with a thin-film die 410 and a white material 411 which extends substantially above the bottom 410 of the die sides. The configuration of FIG. 4(c) may be obtained by a different fabrication process in which the die is first attached, then white material is flown and wets the die; or alternatively, by a fabrication process in which white material is formed on the submount with openings (windows) which expose metal contacts on the submount, and the die is then attached in a window. For a thin-film die, little light (sometimes less than 10% or 5% or 2%) is emitted from the sides, so that the protrusion of white material is not too problematic. Finally FIG. 4(d) shows a volumetric die 420 in which the white material 421 extends upward and eclipses a large fraction of the side 422 and substantially block light.

The aspect discussed above (i.e. the white material does not protrude above the die) may be closely related to the package fabrication process. In particular, the two-metal process which will be discussed below enables such embodiments and the geometries of FIG. 4(a-b). This stands in contrast to a more typical one-metal-layer process where metal contacts are formed, a white reflector with an opening is formed, and the die is attached to the metal layer, yielding the geometries of FIG. 4(c-d).

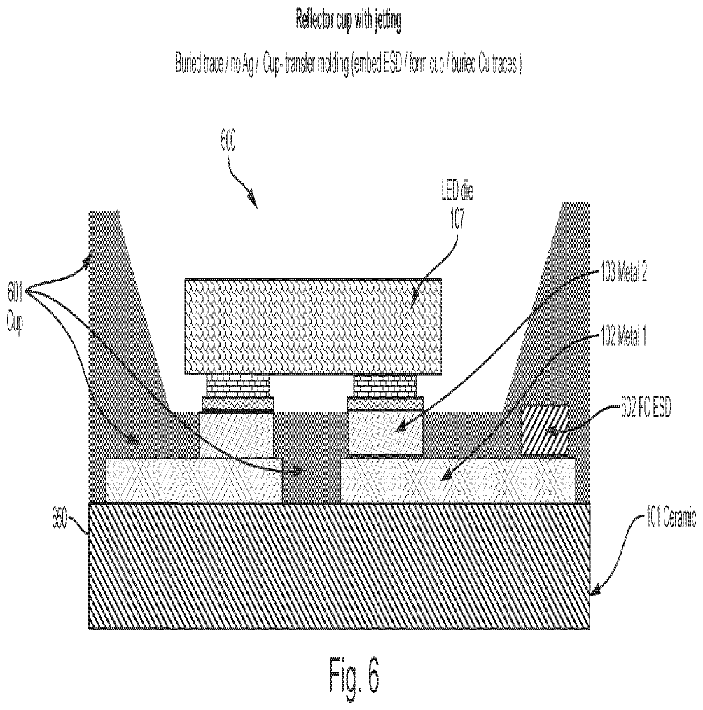

Therefore, in one embodiment, substantially all of the chip extends above the reflective material, or in other words, the reflective material does not extend significantly past the bottom of the chip. Although FIGS. 4(a) and (b) show a layer of reflective material that is flush or below the electrical interface, other embodiments are possible. For example, referring to FIG. 5, other embodiments are shown in which the reflective material is above the electrical interface, but the die is still substantially above it. Specifically, FIG. 5(a) shows a volumetric die 501 with a white reflector 502 that extends above the electrical interface 503, but is still below the bottom 504 of the die. FIG. 5(a) shows a volumetric die 501 with a white reflector 512 that extends above the electrical interface 513 and slightly above the bottom 504 of the die, although substantially all of the sides 520 of the die are still above the reflective material As used herein, substantially all is at least 90% of the area of the sides of the die extends above the reflective material, in another embodiment, at least 95% of the area of the sides of the die extends above the reflective material, and in a particular embodiment, at least 99% of the area of the sides of the die extends above the reflective material. Accordingly, in some embodiments, the package is configured such that at least 10%, 20%, 30%, 40%, or 50% of the pump light escapes form the die sides. This aspect of the invention is especially relevant if the reflective material comes in lateral proximity to the die. For instance, in FIG. 5, the reflective material touches the die sidewall. In FIG. 4, the reflective material is in the direct proximity of the die sidewall. In some embodiments, this proximity is desirable because having a large lateral spacing (or gap) between the die and the reflective material would expose other materials (substrate, metal traces and pads) with lower reflectivity. In some embodiments, the reflector and the die sidewall are separated by lateral distance which is less than 100 um, 50 um, 10 um. In some embodiments there is no lateral distance separating the reflector and the die (for instance the reflector may be present under the edges of the die, which protrudes over the reflector). In the present discussion, reference is made to the reflector formed on the top surface of the package. This should not be confused with the package cup (present in some embodiments and described later): the package cup may be reflective and may protrude vertically over the die, but it is formed at a larger lateral distance from the die (typically larger than 100 um, 200 um, 500 um, 1 mm), such that it does not block light from escaping the die sidewalls.

The reflective layer 106 may comprise a white reflecting material or a dichroic stack. White reflecting materials include diffusing materials which reflect light by scattering. This includes materials comprising a binder (which may be a soft binder like a silicone) and small particles embedded in the binder which scatter light, such as TiO2 (including rutile phase, anatase phase, or a combination of phases including a combination of rutile and anatase), ZnO etc. Such materials comprise so-called white rubbers, and silicone molding compounds (SMCs). White reflecting materials may also be porous materials, including materials having pores of air for scattering, or materials composed of a scaffold of scattering elements with air in-between. For any such material, geometric dimensions (i.e. the size of scattering elements, pores . . . ) may be on the order of 1 nm, 10 nm, 50 nm, 100 nm, 500 nm, 1 um, 5 um, 10 um or in a range including 1 nm-10 um, 10 nm-5 um, 50 nm-5 um, 100 nm-5 um; these dimensions may be a mixture of various dimensions (for instance, scattering particles may have a bimodal distribution around 50 nm and 500 nm, or a broad distribution in the range 50 nm-500 nm, and other such combinations). In one embodiment, the reflective layer is not conductive.

A description of a dichroic stack is given below in the context of the leadframe embodiment, although it applicable to this embodiment as well. When a dichroic is used, the underlying material may be of importance. In such cases, a high-reflectivity metal (such as Ag or Al) may be used to cover the traces, underneath the dichroic.

The substrate 101 may be any structure for providing rigidity and strength to the package and may include for example, metallic leadframes or insulating structures. In one embodiment, the insulating substrate is substantially made of a ceramic. Ceramics offer some advantages over metal substrates. For example, a ceramic's coefficient of expansion (COE) is low, and, thus, it is dimensionally stable through a wide heat range. Moreover, its COE may be similar to that of the LED chip, and thus, the chip and the substrate will expand and contract similarly, thereby reducing stress at the electrical interfaces between the two. In one embodiment, the ceramic comprises one of AlOx, AlN, Al2O3, Si3N4, etc. In one embodiment, the thermal conductivity of the material may be, for example, at least 5, 10, 30 30, 50, or 100 W/(m·K) or in the range 5-200, 20-200, or 50-200 W/(m·K). In some embodiments, the insulating substrate has CTEs in a range of 2.6-6.8 E-6/K (or 1-10 E-6/K) which is very similar to the CTE of the semiconductor which may be ˜5.6 E-6/K (or in a range 1-10E-6/K). The ceramic may be obtained by a variety of manufacturing techniques, including sintering and hot pressing.

In some embodiments, the insulating substrate is not a ceramic but another type of material, including for instance a crystalline or polycrystalline material, or a PCB (including a flex circuit). In this last case, the connections of the PCB or flex circuit can be used to attach the LED.

In some embodiments, the insulating substrate comprises through-vias for backside electrical contacting. In some embodiments, the vias comprise copper or are substantially made of copper. FIG. 1 shows no contacting through-vias, however such vias may be present as shown in other figures including FIG. 3.

Although insulating or ceramic substrates may be preferred for certain applications as discussed above, a traditional metallic leadframe may also be preferred in different applications. For example, leadframes are inexpensive and tend to improve the manufacturability of the package. A description of leadframes is provided below which is applicable to this embodiment as well.

Although any die may be used, the package is particularly well suited for shorter-wavelengths as described above, including violet radiation, ultra-violet radiation, near-UV radiation.

In some embodiments, the package is configured to contain one or more flip-chip LED die. The die may be configured in series, in parallel, or in a series-parallel combination. For example, referring to FIG. 2, the pads and traces are configured to connect the dies is series. More specifically, in some embodiments, each flip-chip LED die 107 bridges the gap between two electrically-isolated traces 102 of a package with the p-contact 108a attached to a pad 103 of one electrically isolated trace, and the n-contact 108b attached to a pad of another electrically-isolated trace 102.

The flip-chip LED die is specially configured to have good die attachment to the package in order to have high reliability, and/or good thermal performance, and/or high performance. This may be achieved with a proper die metal stack 108 and submount metal stack 110. To this end, the submount pads may be further covered with a metal stack 110 suited for die-attachment. The stack 110 may include Ni, Pd, Au or other metals known for die attachment. They may be formed by a technique including ENEPIG (Electroless Nickel Electroless Palladium Immersion Gold) or ENIG (Electroless Nickel Immersion Gold). In one embodiment, the stack comprises a thick Sn layer. In one embodiment, the Sn is on the die side (not the package side) of the stack. In some embodiments, the die stack 108 comprises a relatively thick layer of Sn to provide compliance in the stack. In particular, Sn may be the last metal on stack 108 and may be used for die attach to the package. In the following, we discuss metallization schemes for the LED die; the term die-attach metal refers to the metal stack of the die 108 (either p or n contact) which will make contact to the package metal stack 110. In general, the metal stacks for the p-contact 108a and n-contact 108b may be different, since different metals may be necessary for ohmic contacts to the two LED electrodes.

In some embodiments, the die attach is performed with use of solder alloys. These alloys may include eutectic or near-eutectic gold-tin alloys such as an alloy containing about 80% gold by weight and 20% tin by weight with a reflow temperature above 280 C. Alternately the solder alloy can be primarily tin, such as 100% tin, or tin with alloying elements such as copper and silver for improved mechanical properties. These alloys melt in the range of 200-235 C. Alternately the solder alloy can include bismuth and/or indium with melting temperatures under 235 C, such as the eutectic alloy of 52% indium and 48% tin melting at 118 C. The selection of the solder alloy used may take into consideration: the reactions with the metallization on the package in order to form a strong, electrically conductive, thermally conductive and reliable solder joint; the thermal expansion differences between the package materials and the LED die; the operation temperature of the package; the use of other solders in the assembly of the package into other products; and the methods to apply the solder to the die.

In some embodiments, the die attach is performed with the use of gold-tin solder. The solder alloy may be applied by evaporation, sputtering, plating, or another technique onto the LED die. For example, the gold-tin alloy may be deposited by thermal evaporation from gold and tin sources, or mixed gold-tin alloy sources, as a layer which may be approximately 2 um (or 1, 5, 10 um) thick. The patterning of the layer may be achieved by standard techniques, for instance the photoresist liftoff method, or wet etching, or dry etching, in order to define regions of the die connecting to either the anode or cathode of the LED die. The gold-tin alloy is particularly selected for high reliability applications because of the low chemical reactivity of the solder alloy.

In another embodiment, the die attach is performed with the use of pure tin as the solder material. The tin may be applied by evaporation, sputtering, plating, or another technique onto the LED die. For example, the tin may be deposited by thermal evaporation, as a Sn layer having a thickness of at least about 2, 5, 10, 20, or 50 um, or in a range 2-50 um or 5-20 um. The patterning of the layer may be achieved by standard techniques, for instance the photoresist liftoff method, or wet etching, or dry etching, in order to define regions of the die connecting to either the anode or cathode of the LED die. The use of tin is particularly helpful to accommodate thermal expansion differences between the materials in the package and the LED die. For example, the package may be substantially comprised of aluminum oxide with a thermal expansion coefficient of about 7.2 ppm/C (or a similar ceramic), while the LED die may be substantially comprised of GaN with a thermal expansion of about 3.9 ppm/C. The high ductility of tin, the low elastic modulus, the ability to economically apply thick layers, and the lower melting temperature all favor tin and high-tin solders over gold-tin eutectics for accommodating thermal strain differences between the LED die and the package. In the case of package materials with larger thermal expansion coefficients and/or longer lengths between the anode and cathode solder contacts, die with gold-tin solder may suffer from cracks in the solder resulting in an open circuit after die attach, due to the different thermal contraction of the die and package after cooling from reflow temperature.

In an experiment, the package was a leadframe package which substantially consisted of silicone molding compound with a thermal expansion coefficient of about 50 ppm/C and copper with a thermal expansion coefficient of about 17 ppm/C. In this experiment, a portion of LED die had electrical opens after reflow due to solder cracks in the case of using 1.7 microns of gold-tin solder. This portion was reduced when using 5 microns of tin as the solder material.

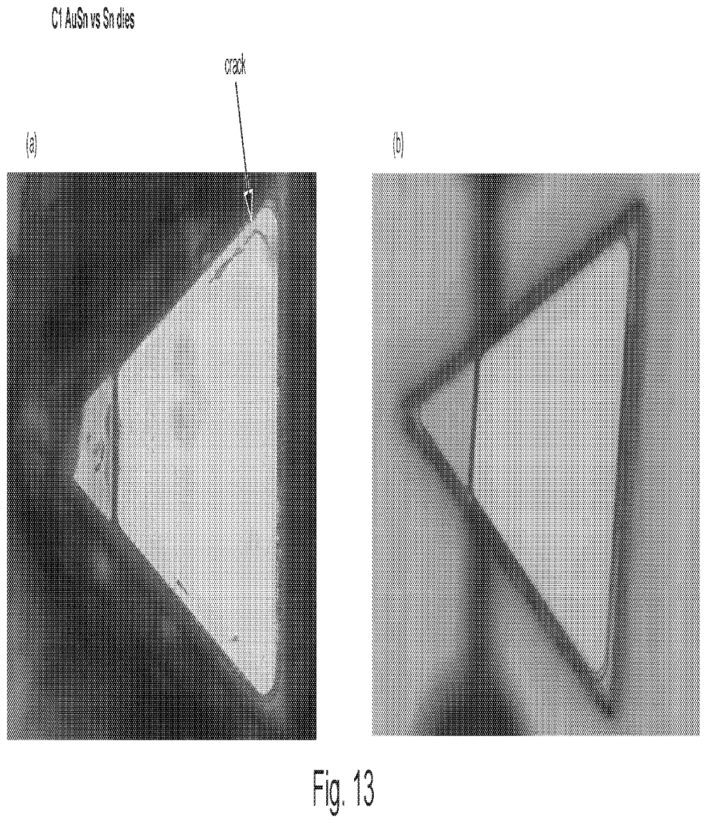

FIG. 13 illustrates the beneficial effect of Sn die-attach. In this experiment again, an AuSn-based die and a Sn-based die were assembled in leadframe packages. After reflow the AuSn die was damaged and became leaky. Microscope imaging the die through its polished top-surface revealed a crack in the p-metal stack, as show on FIG. 13(a). This crack enabled metal migration and shorting (as confirmed by cross-sections). It is attributed to the mechanical strain of the package and the lower compliance of the AuSn die-attach. In contrast, FIG. 13(b) shows that the Sn die showed no such defect thanks to its better compliance. Such results have been repeated on large amounts of dies.

In some embodiments, the substrate and the die may have thermal expansion coefficients which differ by less than 5 (or 10 or 3) ppm/C.

Even in packages with good thermal expansion matching between the substrate and die, Sn die-attach may be desirable. For instance, the submount may still incorporate metal traces which are thick enough that their thermal expansion may have a detrimental impact on the die reliability. For instance, in dual-metal packages such as those of FIG. 1, the total height H1+H2 of the metal stack may be large—say tens of um or above 50 um, 75 um, 100 um. In such cases, Sn die-attach may have a beneficial effect just like in leadframe packages.

In order to accommodate height differences in the package and LED die, the solder may be deposited over different regions with different wettability to achieve different solder thicknesses after melting. The details of this design are described in US patent application U.S. Ser. No. 14/615,315, which is incorporated by reference. Besides wetting control, layers are provided under the dewetting layer to limit the reaction and penetration of the solder alloy toward the anode and cathode contacts, and to provide additional mechanical compliance. These layers may be selected specifically for a tin die-attach metal. For example, tin can dissolve and/or react with substantial amounts of gold during reflow. This reaction may have undesirable impact on the solder reliability or mechanical properties, like the formation of brittle intermetallic layers. On the other hand, materials with very low chemical interaction with the solder may not form a strong solder joint. For example, chromium acts as an excellent barrier against tin penetration, but the interface between these metals is very weak. Other materials have an intermediate reaction rate which allows for strong interface formation with limited formation of brittle intermetallics. For example, barrier layers of titanium, nickel, and platinum will react slowly with tin during reflow. These layers may be deposited by various techniques, for example by evaporation or sputtering. In the case of film defects arising from the deposition process, it is advantageous to provide multiple layers of alternating materials in sequence, such that the defects in first layers are covered and protected by following layers. In an example, a barrier stack is provided with 3 pairs of 100 nm Ti and 100 nm Pt deposited by electron beam evaporation. Other material combinations and thicknesses are possible to provide the function of a barrier to tin penetration to the anode or cathode contact without formation of detrimental brittle layers. In another example, a sequence of 100 nm Ti, 50 nm Ni, 50 nm Ti, 100 nm Pt, 50 nm Ni, and 80 nm Pt provided the barrier to tin solder reflow. In another example, a thick layer of a more ductile metal or alloy is provided under the solder barrier to further accommodate mechanical strain from the assembly process or package. For instance, 500 nm of gold or 1 um of aluminum may be deposited above the anode and/or cathode contacts and below the barrier layers to provide mechanical compliance.

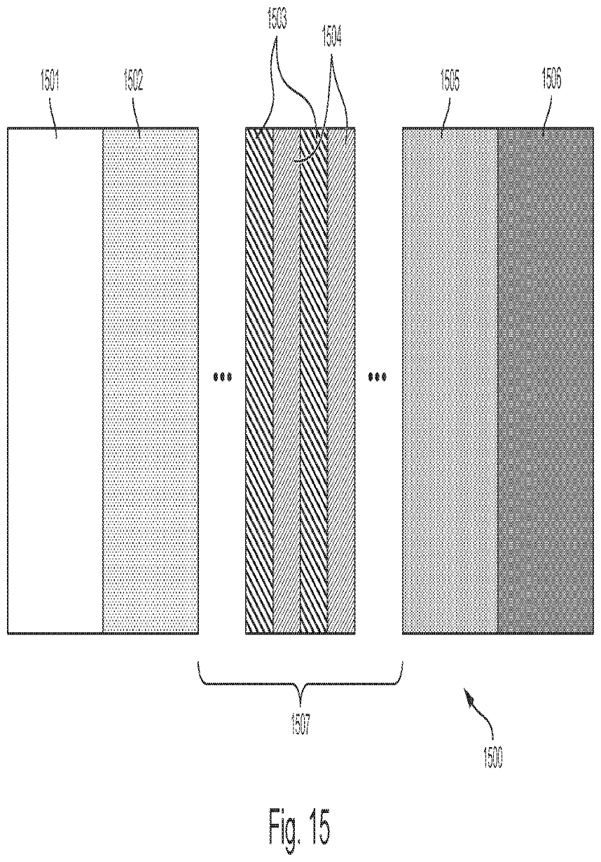

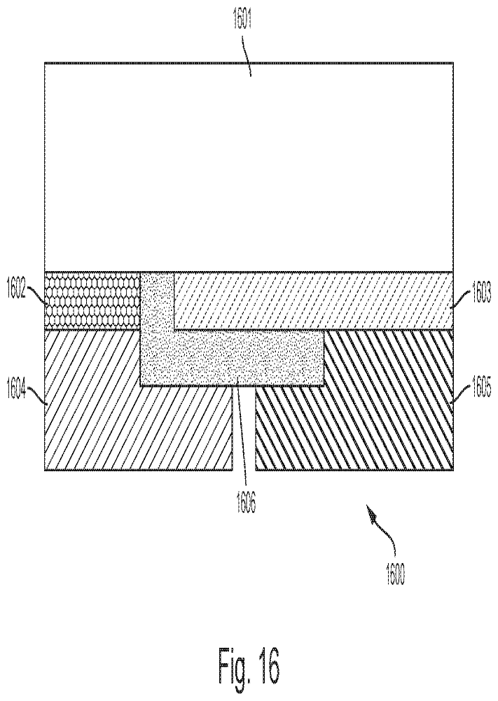

Referring to the FIG. 15, in some embodiments, the metal stack 1500 (for the p- and/or n-contacts) is as follows:

GaN 1501/[contact metal stack 1502]/P*(Ti 1503/Pt 1504) 1507/[intermediate metals 1505]/Sn 1506

Or, more generally:

GaN 1501/[contact metal stack 1502]/P*(Ti 1503/metal 1504) 1507/[intermediate metals 1505]/Sn 1506

Where P is an integer which may be 1, 2, 3, 4, 5, 8, 10 or in the range 2-10 and “P*” denotes a multiple repeat 1507 of the 2-layer stack (1503/1504) in parenthesis. The contact metal stack 1502 may comprise a high-reflectivity metal including Ag. It may be configured to form an ohmic contact to the p-type or n-type semiconductor material of the LED die. The contact metal stack and the intermediate metal stack may further comprise some of the following metals: Ti, Pt, Au, Al, Ni. Here GaN is taken as an example, but other materials including semiconductors can be used.

The solder material may also be selected to form a bond with the package metal materials with good mechanical and thermal properties. The solder material may react with the package finish 110. For example, the package finish may consist of electroplated silver or electroless nickel/immersion gold, or electroless nickel/electroless palladium/immersion gold. In the case of tin solder and a silver finish, the molten tin may dissolve some silver from the package and form silver-tin intermetallics. In the die attach process, a flux may be applied to reduce surface oxides on the solder and package to promote the formation of a strong bond. For example, a resin-mildly activated flux (RMA flux) may be applied and the package-flux-LED die assembly heated to above 232 C to melt the tin solder and form the bonds with the package and die metallizations.

In some embodiments, the various metals are selected to enable die-attach with a reflow temperature higher than 150 C but lower than 260 C, or in the range 180-250 C, 200-240 C.

In another embodiment, the die attach may be performed with the use of an anisotropic conductive paste that is dispensed on the package. The die is placed into the paste and a heat treatment is applied to form the connection. In this case it is not necessary to apply a solder material to the LED die itself. Similarly, the die attach may be performed using conductive epoxy which is cured to form the electrical contact. In these cases the selection of the metal between the paste or epoxy should be chosen for compatibility with assembly and use temperatures such that the anode and cathode contact materials are not degraded. For example, a barrier layer or layers may be added above the anode and cathode contacts for chemical, metallurgical, mechanical and electrical stability. For example, a final surface layer of gold or platinum may be used to prevent the accumulation of surface oxides that could impede formation of electrical contact. Under the final layer may be a layer of titanium and nickel to provide adhesion to underlying materials and a diffusion barrier between the paste or epoxy and the die contacts. In an example, layers of 100 nm titanium, 100 nm nickel, and 50 nm gold are provided on the die. Other layers may be included to improve the diffusion barrier and final surface, including titanium-tungsten alloys, chromium, zirconium, vanadium, tantalum, molybdenum, cobalt, copper, aluminum, palladium, rhodium, their alloys, and in various combinations.

In some embodiments, the n- and p-metals 108, on the die-attach side, have a separation which is suited for high-yield die attach but within reason given the die dimension. For instance, the separation may be at least 30, 50, 100, 150, or 200 um on a die having a typical lateral dimension in the range 250-500 um. This enables die attach to packages having larger critical dimensions. For instance, if the electrodes 110 on the package surface are separated by a gap of width W, the separation on the die side may be scaled to adapt to this value. For example, it may be at least 50%, 75%, 100% 125%, or 150% of W. Those of skill in the field might appreciate that a small die requires a gap distance which is a fraction of the die, and the gap in the package needs small as well. Certain package technologies such as copper leadframe shaped by wet etching might have difficulties reaching gaps below 150 um, therefore limiting the choices for small dies of similar dimensions. The package technologies presented here on isolated submounts are capable of reaching an aspect ratio of 1:2, 1:3, 2:1, or 3:1, or an aspect ratio in the range 1:2-2:1 between metal thicknesses and lateral gap width. Therefore, a copper thickness of about 80 um can achieve a gap of about 80 um, thus allowing for a die of 350 um in width to have a reasonable spacing gap between the electrodes, for example, 100 um. Therefore, in one embodiment, the lateral dimension of the chip is less than 500, 400, 350, or 300 um, and the gap between electrodes is less than 150, 125, 100, or 75 um.

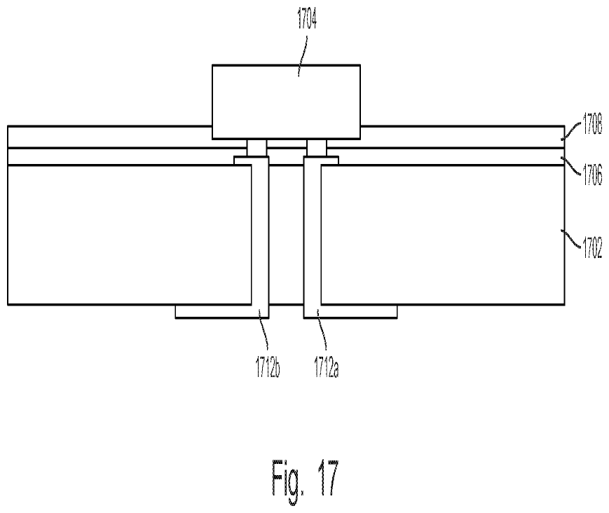

Referring to FIG. 16, in some embodiments, the die 1600 is a flip-chip die having a contact redistribution scheme. That is, the areas of the die's n-contact 1602 and p-contact 1603 on the epi side 1601 are different from the areas of the n-contact 1604 and the p-contact 1605 on the die-attach side. Typically, the p-contact is maximized on the epi side (for instance, at least 80% or 90% of the die footprint is p-contact) to reduce droop. On the other hand, the balance of areas may be different on the die-attach side: for instance the n-contact may occupy at least 20% or 30% or 40% of the die footprint. Dielectric materials 1606 may be used to insulate the n- and p-metals.

It should be appreciated that the selection of metallization for the die and package, as discussed above, may interact with other aspects of the invention.

For instance, it may enable reflow at a low temperature (i.e. below 280 C or below 250 C)—this in turn may enable the use of other materials in the package which are incompatible with process temperatures. For instance, the white reflector material or the protective barrier may be compatible with a process step at 230 C but not at 280 C.

Additionally, the die metallization may enable desirable die architectures. For instance, small flip-chip dies may be more prone to die shear because the contact areas are small (in contrast to legacy flip-chip dies, having an area of about 1×1 mm\hat{ }2). Therefore, in contrast to the conventional AuSn die-attach, the use of Sn as a die-attach metal enables small flip-chip dies with good die attach. In some embodiments, the die is flip-chip with a base area of about 250\hat{ }2 um\hat{ }2 (for instance a square die having a 250 um side, but other shapes like triangle are possible), or less than 500\hat{ }2 (or 300\hat{ }2, 200\hat{ }2, 100\hat{ }2) um\hat{ }. This is combined with a Sn metal in the p- and/or n-stacks to ensure good die attach.

Further, in some embodiments, the die is volumetric. A volumetric die may be defined by a thickness of at least 50 um (or 20, 80, 100, 150 um) or a thickness in the range 20-500 um, or by a ratio of height divided by characteristic lateral dimension (as defined below) which is above 10% (and sometimes on the order of unity). This is in contrast to thin-film dies where the die thickness may be about 1-10 um thick whereas its side (or characteristic lateral dimension) may be about 0.5-2 mm wide. This volumetric aspect further strengthens the die, in contrast to a thin-film die. In some embodiments, the volumetric die has a bulk conductive die substrate, which may comprise a III-Nitride substrate or a bulk GaN substrate or SiC or ZnO or GaOx or other conductive substrate (preferably transparent); in other embodiments the die substrate may be insulating and transparent, such as sapphire. In volumetric flip-chip embodiments, the die substrate faces upward (above the die epi); a transparent substrate may help light escape from the die sides. In some embodiments, at least 10% or 20% or 30% of the light emitted by the die escapes from its sidewalls.

In some embodiments, a good die attach aptitude is characterized by a sufficient die shear strength. For a die having an area of about 60,000 um\hat{ }2, a desirable die shear value may be above 200 g, 250 g, 300 g. The shear force may scale with the area of the die.

The present teachings on die-attach metals may be especially suited in situations where mechanical compliance is required. This may arise if the lateral dimensions of a flip-chip die are small, as previously mentioned. A characteristic lateral dimension for a die may be defined as the square root of its area (meaning the area of its top-view footprint). When the characteristic lateral dimension is lower than 500 um (and lower than 400 um, 300 um, 200 um, 100 um), mechanical compliance may be necessary. In various experiments of Applicants, the characteristic lateral dimension is 250 um. Further, mechanical compliance may be desirable if the flip-chip die is contacted to a metal layer which is thick enough. For instance, even if metal traces are formed on top of a ceramic substrate, thick traces may have enough thermal expansion that they may cause die damage. This may arise if the thickness of the trace is larger than 30 um, 50 um, 100 um. In this context, the relevant trace thickness is the total thickness of metal beneath the die: for instance with reference to FIG. 1, it is the thickness H1+H2.

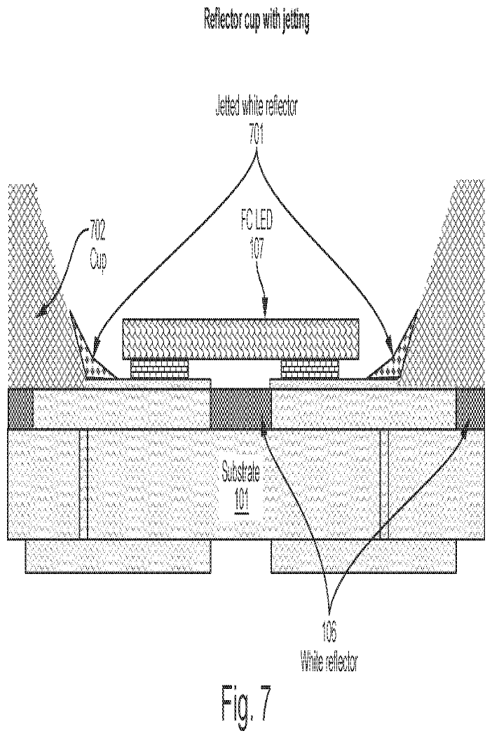

In some embodiment, additional structure or features are provided on the submount to improve the package's performance. For example, in some embodiments, the phosphor material is contained within a cup, which may be formed on the submount. FIG. 6 shows a cross-section of one embodiment of a package 600 having cup/cavity 601 formed on top of the submount 650. Here the submount comprises the substrate, metal layers, and surface reflective material. This cup can be produced using for, example, injection, transfer or compression insert molding. Or it could be fabricated separately by molding a stamped sheet of silicone or attaching a laser-cut ceramic plate. Or it could be drawn by dispensing reflective material (such as a white rubber material) in a close shape. Still other embodiments will be understood by one of skill in the art in light of this disclosure. In some embodiments, when cup is bonded to the submount, it features a bonding layer with a bonding layer thickness (BLT) which may be less than 5 um, 10 um, 25 um 50 um. In some embodiments, the bonding layer has a high reflectivity and/or its thickness is minimized to avoid optical losses. In cases when the cup is molded, it may be formed in the same step as the surface reflector. The cup may be used to dispense a phosphor material within. In this case the light-emitting area for emitted light (comprising pump light and phosphor converted light) may be defined by the top surface of the cup. Alternatively, the phosphor material may be formed on the die (for instance in the case of a chip-scale package die or of a conformal-phosphor film on a die): in these cases the cup may still be useful to contain the light emitted by the phosphor and control its lateral propagation.

In some cases the package comprises an ESD die 602 which is a flip-chip ESD die. In such cases, the cup may be molded on top of the ESD, after the ESD is attached to the package, to avoid light absorption by the ESD.

Referring to FIG. 7, to increase the optical package efficiency, white reflector may further be jetted in various parts of the package. The jetted white reflector 701 may have a high reflectivity. It may be jetted at the interface where the submount 750 meets the cup 702 as shown in FIG. 7. This hides the BLT of epoxy and forms a more proper cup. In cases when an ESD chip is present in the package, the jetted white material may also be used to cover the ESD chip (and hence reduce its light absorption). In addition to jetting, other local dispense methods can be used for dispensing the white material. In some cases, a local dispense method is used which can dispense white reflecting materials with minimum lateral feature size below 100 um (or 50, 20, 10 um).

In another embodiment, the package combines some of the features described previously. For example, it comprises the dual trace/pad structure for FIG. 1, the transfer-molded reflector cup which also covers the FC ESD, and the white high-reflectivity reflector material fills the top of the package up to the top of the pad.

In other embodiments, no cup is present. Instead, the phosphor material may be dispensed over several packages at once (i.e. at the tile level). The dispense process may be dispense from a needle dispense tool, jetting, spraying, printing, conformal film coating, or other known phosphor processes. The packages may later be singulated (for instance by sawing/breaking the tile), and the phosphor may also be separated during such a singulating step. In such cases, the package side may comprise the phosphor side (as well as the side of the insulating substrate, etc. . . . ) and light may be emitted from the package side as well as its top side.

Further, in some embodiments, the top of the phosphor material is covered with a reflector (which may be a white reflector or a specular reflector). The reflector may be formed directly on the phosphor, or an air gap may be present. In such embodiments, light may be emitted from the sides but not the top. Further, some of the sides may be covered with a reflector such that only some sides (or only one side) emit light. Such packages constitute a form of side-fire (or side-emitter) package which may be useful in display applications and for waveguide/lightguide coupling; however they contrast with standard sidefire packages where the top surface of the package emits light and the package is merely tilted on its side.

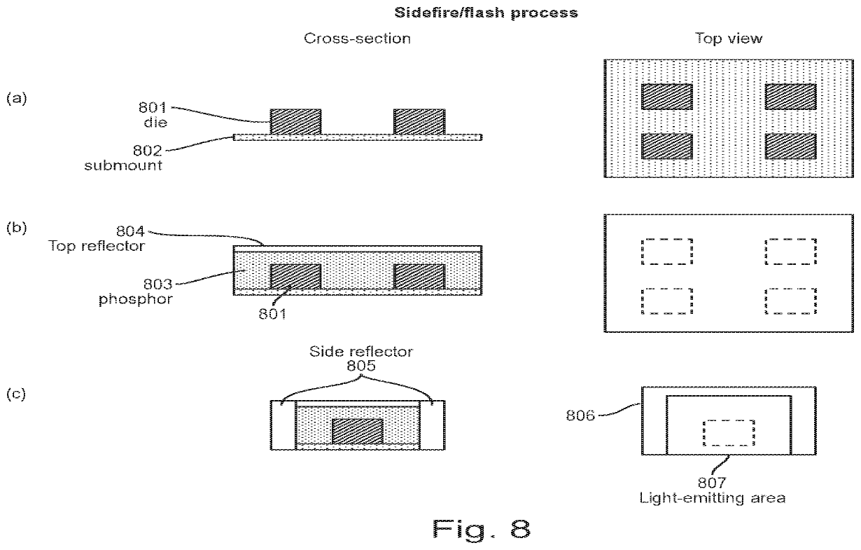

FIG. 8 illustrates a possible fabrication process for such embodiments. In FIG. 8(a), the dies 801 are attached on a tile 802 of package submount (for simplicity, the detailed structure of the submount is not shown; it may correspond to one of the configurations described herein, including a ceramic substrate with metal traces and a reflector). In FIG. 8 (b), the tile 801 is covered with a phosphor 803. The phosphor may be dispensed by a variety of techniques, including a phosphor-silicone-slurry dispense (for instance with a needle dispenser), spraying/spray coating/jetting, printing (including screen-printing). It may have a planar top surface, although this is not required. A top reflector 804 may also be formed. This may be one of the reflector materials discussed in this application, and be formed by spraying, dispensing, molding, mechanical attachment or gluing. In FIG. 8 (c) the dies are singulated into packages (a package may comprise one or several dies). The singulating may be achieved by cutting, sawing, scribing, cleaving, laser cut or other techniques. Further, a side reflector 805 may be formed on some or all the sides of the package. In FIG. 8 (c), the package 806 is shown with a top reflector and one open side facet 807. In this case, the side facet becomes the light-emitting surface. Conversely, if all sides are covered and the top facet of the phosphor is clear, the top facet becomes the light-emitting surface. In some cases, only a fraction of a facet is clear and constitutes the light-emitting surface.

In some cases, the top and side reflectors are formed in a single step. In some cases, partial singulation is done (for instance, only singulating some facets of the final package); then the side reflector is formed (for instance it is dispensed in the streets of the partially-singulated packages); then singulation is finalized to expose open surfaces which become the light-emitting surfaces. In some cases, there is an air gap between some or all phosphor surfaces and some or all reflector materials.

Various aspects of the geometry of such a package may be relevant. The dies may have any shape, including having a square base, a rectangle base, a triangle base, a diamond base. The dies may be volumetric. In some cases, the thickness of the die is at least 10% (or 20%, 30%, 50%) of the height of the phosphor material. The singulation may form a package with a square footprint, a rectangular footprint, or other shapes. The light-emitting surface may have a shape that is square, rectangular, triangular, or others.

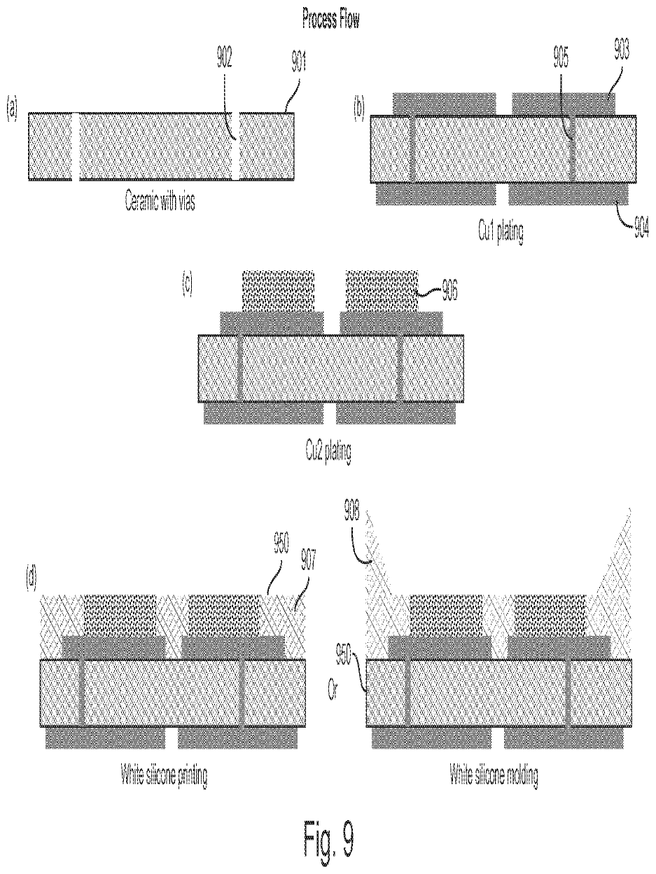

Referring to FIG. 9, one embodiment of the process of making a submount 950 is shown. In step (a), a ceramic substrate 901 is provided. In this particular embodiment, the ceramic substrate has a number of bores 901 for vias 905.

In step (b), the traces 903 are plated on the substrate. In so doing, the vias 905 are filled. In this particular embodiment, the bottom of the substrate is also plated with contacts 904 such that the traces 903 are connected to the bottom contacts 904 through vias 905. In step (c), the pads 906 are added to the traces. It should be understood that traces/pads may be formed by a variety of techniques, including sputtering and/or plating, including electroplating. The metal traces may be made of any conductive material including, for example, copper, aluminum, gold, etc. For instance, in one embodiment, package 100 comprises copper traced and pads. The traces may have a thickness of up to about 5, 10, 15, 20, 25, or 30 um, or a thickness in a range 10-30 um. The pads may have a thickness up to about 40, 40, 50, 60, 70, 80, 90 100, 120, or 150 um, or a thickness in a range 20-200 um or 40-100 um.

In such double-layer packages as shown in FIG. 1, the planar layout of the traces and pads does not have to be identical. For instance, the traces may run across the package and provide electrical connection while the pads may only be present locally to provide die-attach pads. Furthermore, the layout of the pads may be configured to minimize their surface coverage. For instance, the pads may substantially have the same footprint as the die, such that the die substantially or completely covers the electrical interface areas.

In step (d), the reflective material 907 is added to the submount. This ensures good reflectivity of the reflector over the traces—for instance more than 90% at all wavelengths in the range 400-700 nm. In one embodiment, the reflector material is polished off to leave a flush finish with the pads 906. A mold may be used to form reflector material into a cup 908 (described above). In such cases, the planar reflective material 907 covering the package surface and the cup 908 may be formed in the same molding step. In some embodiments, the white reflector is formed before the LED die is attached, rather than dispensing white reflector after die attach. Doing so facilitates having a white reflector that is flush with the package, rather than the LED die, which can be advantageous, especially for a volumetric die.

A more detailed step list of a possible process flow is listed below. This list corresponds to a process where the cup 908 and reflective layer 907 are formed together:
1. Sputter seed metal
2. Photo image
3. Cu1 Plating
4. Photo image
5. Cu2 plating
6. Polish bottom Cu
7. Striping/Etching
8. Polish top Cu
9. ENEPIG or ENIG to form metal stack on top of Cu2
10. Die-attach of ESD chip
11. Mold reflector cup and package reflector with reflective material such as SMC
12. De-flash SMC on tile
13. Die-attach of LED chips
14. Dispense phosphor

Some embodiments make use of a substantially transparent material for encapsulating the LED die and/or for forming a binder for luminescent materials (also referred to as phosphors herein, although a variety of material known in the art can be used, including quantum dots). The high transparency ensures reliable operation.

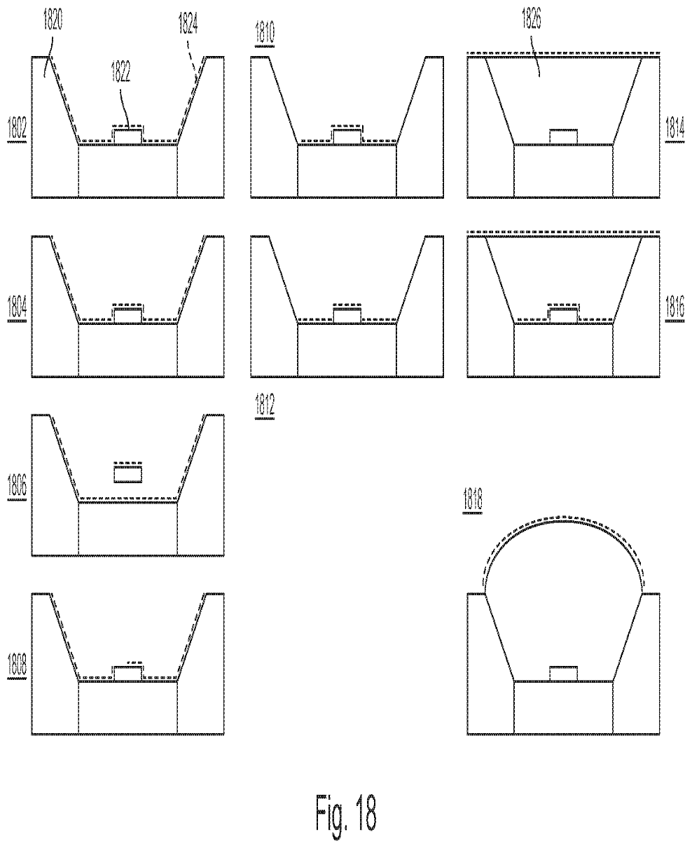

FIG. 17 illustrates the transmission of various binders. It shows the absorption coefficient 1700 (in cm−1) of two silicone materials. For a high-index (n˜1.5) phenyl silicone, the absorption 1701 is rather high. It is above 0.1 cm−1 at wavelengths below 500 nm, and above 0.15 cm−1 at wavelengths below 430 nm. Not all high-index silicones show such absorption at all visible wavelengths; however, they often display an undesirable high absorption at short wavelengths. In contrast, for a lower-index (n˜1.41) methyl silicone, the absorption is below 0.05 cm−1 at all wavelengths. Here the true absorption may not be resolved by the measurement (based on transmission and reflection), and it may be substantially below 0.05 cm−1. Some embodiments make use of a binder having a low absorption at short wavelength, in a short-wavelength range (as described earlier), or at the peak wavelength of the pump LED. Suitable low-absorption values may be less than 0.1 cm−1, 0.05 cm−1, 0.02 cm−1, 0.01 cm−1, 0.005 cm−1. These may be achieved by some silicones, but also other materials including glasses, sol-gels, organics including poly-silazanes. Some of these materials may combined a desired high transparency with a desired high index, including higher than 1.3, 1.4, 1.5, 1.6, 1.7, 1.8. In some cases the index may be increased by inclusion of high-index particles (such as nanoparticles of AlOx, ZnO, TiOx, NbOx, etc).

FIG. 17 illustrates a light emitting diode (LED) package 1700. In the illustrated embodiment, LED package 1700 includes a submount 1702, violet LED die 1704, at least one reflective layer 1706 and protective coating 1708. The violet LED die 1704 is coupled to the submount 1702 and the at least one reflective layer 1706 is disposed over at least a portion of the submount 1702. Further, the protective coating 1708 is disposed over at least a portion of the reflective layer 1706.

In one embodiment, LED package 1700 further comprises an encapsulant disposed over the violet LED die 1704 and the at least one reflective layer 1706. In various embodiments, the encapsulant is additionally disposed over the at least one protective coating layer 108. In various embodiments, the encapsulant comprises one or more wavelength-converting materials configured to convert at least a portion of light emitted by the violet LED die 1704.

In one embodiment, submount 1702 comprises an insulating substrate comprising terminals for carrying electrical power. For example, the submount 1702 may comprise a ceramic material with metallic regions forming the terminals, 1712a and 1712b. The metallic regions may include through-vias and metal on a top and bottom of the submount 1702. In one embodiment, the metallic regions comprise copper and a top surface of the copper is further covered with metals including Nickel (as diffusion barrier) and the one or more reflective layer 1706. In various embodiments, the regions between the terminals 1712a and 1712b may be coated with a non-metallic reflecting material. For example, the regions between the terminals are coated a white reflector. In one or more embodiments, submount 1702 is a lead frame and/or may have one or more angled regions. In particular, 1702 may have a body which is substantially made of metal leads (including copper), or of metal leads and an injected material such as a silicon molding compound.

In one embodiment, the violet LED die 1704 emits violet light. For example, the violet LED die 1704 may be configured to emit violet light within a peak within a range of 400 nm to 430 nm. As is illustrated in FIG. 17, the LED package 1700 comprises a single violet LED die. However, in other embodiments, the LED package 1700 comprise more than one violet LED die. In one embodiment, the violet LED die 1704 comprises a triangular shape or a square shape. Further, the violet LED die 1704 may be a flip chip die.

The violet LED die 1704 is coupled to the submount 1702. In one embodiment, the violet LED die 1704 comprises two or more pads that are coupled to corresponding terminals (1712a and 1712) of the submount 1702. In one embodiment, the pads of the violet LED die 1704 are coupled to the terminals of submount 1702 through solder joints.

In many embodiments, the violet LED die 1704 provides various advantages in many lighting applications. However, in many embodiments, the use of a violet LED die precludes the use of a phenyl silicone encapsulant, because of photo-chemical reactions which may lead to a degradation of the silicone and/or materials in contact with the silicone, such as the reflective layer. Further, in various embodiments, some organic-based coatings degrade under violet light and may be not be used in packages having a violet LED die.

For light sources employing a blue LED die, with a peak wavelength within a range of about 440 nm-about 490 nm, standard phenyl silicones may be used and act as barrier for a reflective layer. However, for light sources employing a violet LED die, with a peak wavelength within a range of about 390 nm-about 430 nm, phenyl silicones become absorbing and unreliable. Additionally, in various embodiments, while binders such as a methyl silicone can be used in embodiments employing a violet LED die, such binders may not adequately protect the reflective layer from atmospheric agents and the reflective layer may degrade. Suitable low-absorption binders are described elsewhere in this application. Thus, in various embodiment, a protective coating (e.g., protective coating 1708) may be deposited over the reflective layer (e.g., one or more reflective layers 1706) to improve the performance and reliability of LED packages comprising a violet LED die.

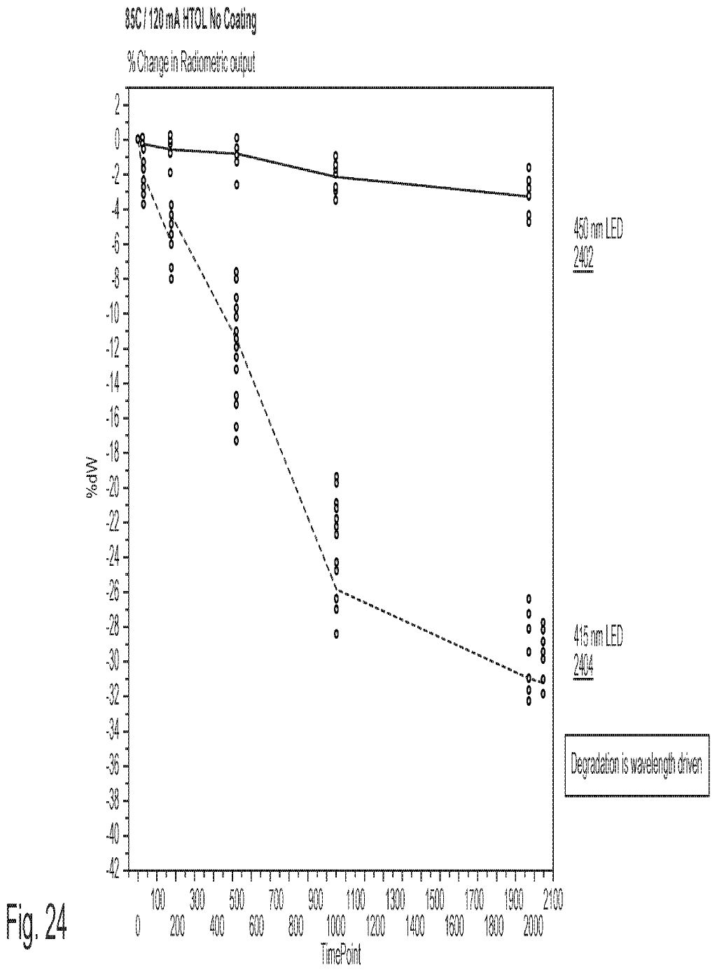

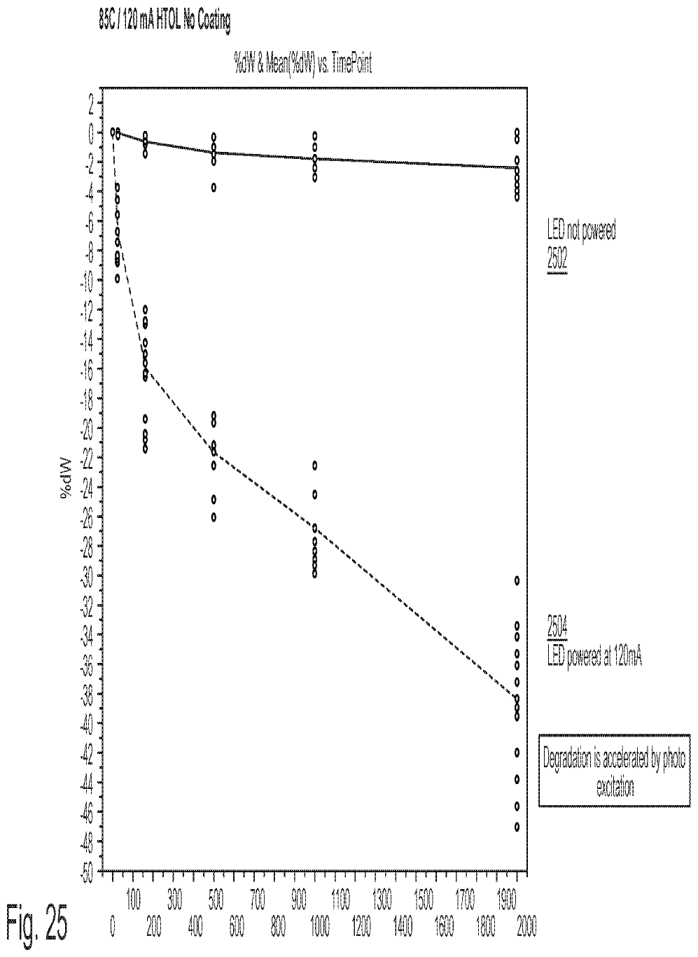

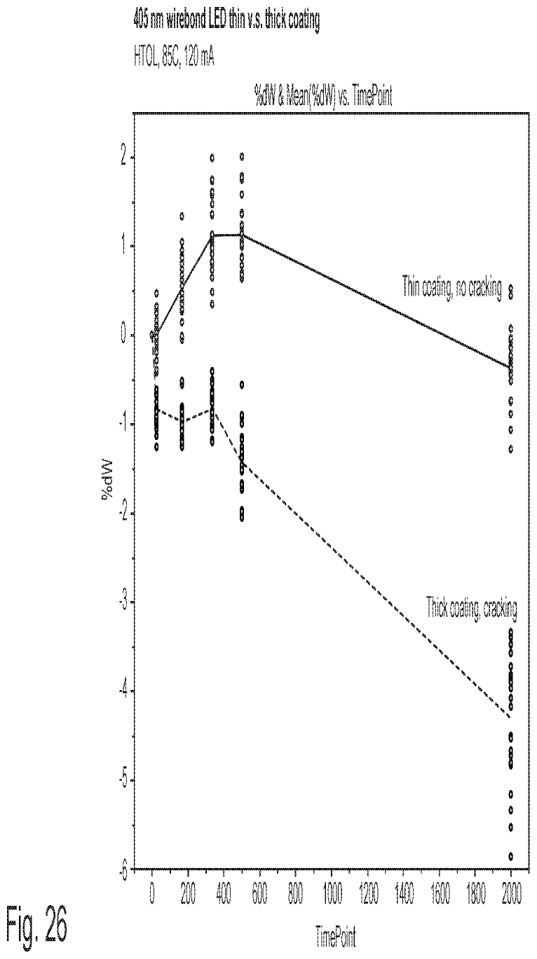

FIG. 24 illustrates degradation of a reflective layer due to light emitted by a violet LED. FIG. 24 shows the radiometric flux of two types of emitters over time, a first emitter has a blue LED die configured to emit light with a peak wavelength around 450 nm and a second emitter has a violet LED die configured to emit light with a peak wavelength around 415 nm. Both emitters use a standard phenyl silicone encapsulant. Both emitters comprise a lead frame package and are driven at 120 mA at a temperature of 85° C. As can be seen, the first package exhibits minimal degradation as shown by 2402, while the second package exhibits severe degradation as shown by 2404.

FIG. 25 shows the radiometric flux for an emitters using a violet LED and lacking a protective coating over time and under different operating situations. For example, 2502 shows that the radiometric flux of an emitter is maintained if it is stored and not operated. However, as is shown by 2504, if the violet LED is powered, the radiometric flux decreases similar to as is shown in FIG. 24. Thus, it can be concluded that in some cases degradation is accelerated by a process related to violet light (photo-excitation).

Returning to FIG. 17, the at least one reflective layer 1706 is disposed over at least a portion of submount 1702. In one embodiment, the at least one reflective layer 1706 comprises a reflective metal. For example, the at least one reflective layer 1706 comprises silver. Further, the at least one reflective layer 1706 may comprise multiple layers of a single material or multiple layers of different materials.

In various embodiments, the at least one reflective layer 1706 differs with some conventional packages which use other metals such as aluminum. While aluminum may be more reliable than silver, it is less reflective especially for light wavelengths above 390 nm. Therefore, silver may be preferable in embodiments that include a violet LED as the LED die.

In some embodiments, the at least one reflective layer 1706 has a normal-incidence reflectivity which is higher than 98% (or 99%, or 99.5%, or 99.8%) at a wavelength in the range 400 nm-700 nm. Further, in some embodiments, the at least one reflective layer 1706 has a normal-incidence reflectivity which is higher than 90% (or 95%, 97%, 99%) at all wavelengths in the range 400 nm-700 nm. In some embodiments, the at least one reflective layer 1706 has a reflectivity which is higher than 90% (or 95%, 97%, 98%, 99%) at all wavelengths in the range 400-700 nm, when averaged over angles of incidence as explained below.

The protective coating 1708 is disposed over at least a portion of the at least one reflective layer 1706. In one embodiment, the protective coating 1708 is disposed over the entirety of the at least one reflective layer 1706. In other embodiments, the protective coating 1708 is disposed over at least a portion the violet LED die 1704.

In various embodiment, the least one protective coating layer 1708 may be referred to as a barrier as it protects the at least one reflective layer 1706 from atmospheric agents. For example, the least one protective coating layer 1708 is compatible with short-wavelength operation (violet light) and protects the at least one reflective layer 1706 from degradation from one or more of short-wavelength light, sulfur, oxygen, and heat.

Various tests for assessing reliability and degradation will be described in the following.

The protective coating 1708 may be formed of inorganic materials such as SiOx, AlyOx, TiOx, NByOx, AlSiOx, SiNx, ZrOx, transparent oxide, glass, or organic materials such as polyvinyl alcohol, aminopropyltriethoxysilane, ethylene vinyl alcohol, (poly)-siloxane, (poly)-silazane or triazine based coating. The coating layer may be dispensed as a spin-on coating and cured; it may be spray-coated; it may be vapor deposited; it may be deposited by sputtering, evaporation, ALD, CVD; other deposition methods are possible.

In various embodiment, the thickness of the protective coating 1708 is configured to provide a barrier to gases. For example, it may be at least 10 nm, 50 nm, 100 nm. In various embodiments, the thickness should be low enough to avoid cracking due to thermal or mechanical stress. For example, it may be less than 1000 um, 100 um, 10 m, 1 um, or 5 um. In some embodiments, the thickness is in a range of 100 nm to 10 um. In one embodiment, the thickness of the protective coating 1708 is about 1000 nm and is comprised of least one layer of AlSiOx.

In one or more embodiments, one or more parameters of the protective coating 1708 may be configured to provide and/or optimize one or more protective effects. For example, one or more of a chemical composition, viscosity, porosity, elasticity, and permeability may adjusted to provide and/or optimize one or more protective effects. In various embodiment, the viscosity of the protective coating is in a range from 1 cp to 30,000 cp. Further, the water and oxygen permeability of the protective coating is in a range from about 0.01 cc/m2/24 hour-about 10 cc/m2/24 hour. Additionally, the Young's modulus of the protective coating is in a range from 0.001 to 50.

In one embodiment, the protective coating TS 108 is solvated in a low viscosity solvent, dispensed, drop casted or spray coated into a cup, allowing the solvent to evaporate at room temperature or at elevated temperature, and after the film has dried, the protective coating layer is cured. In other embodiments, the protective coating 1708 is solvated in a low viscosity solvent, spray coated on a planar submount, allowing the solvent to evaporate in air or at elevated temperature, and after the film has dried, the protective coating is cured. In various embodiments, the protective coating 1708 is drop casted or dispensed directly into the package with a well-defined cup without the use of solvent or dilution. The protective coating 1708 may be cured after it is drop casted or dispensed. In one or more embodiments, the protective coating 1708 may be applied using thin-film deposition methods such as Atomic Layer Deposition (ALD), or Chemical Vapor Deposition (CVD), or Plasma Vapor Deposition (PVD).

In one or more embodiments, the protective coating 1708 may serve as a binder for one or more phosphors—in which case the protective coating may simultaneously act as an encapsulant.

In various embodiments, depending on the protective coating elasticity, hardness, thickness, thickness uniformity, curvature, topology of the submount, surface energy of the reflective layer, surface cleanliness, presence of LED, ESD and/or other components inside the package, the final cured proactive coating 1708 may or may not have cracks. In some embodiments the barrier does not present any crack longer than 20 microns.

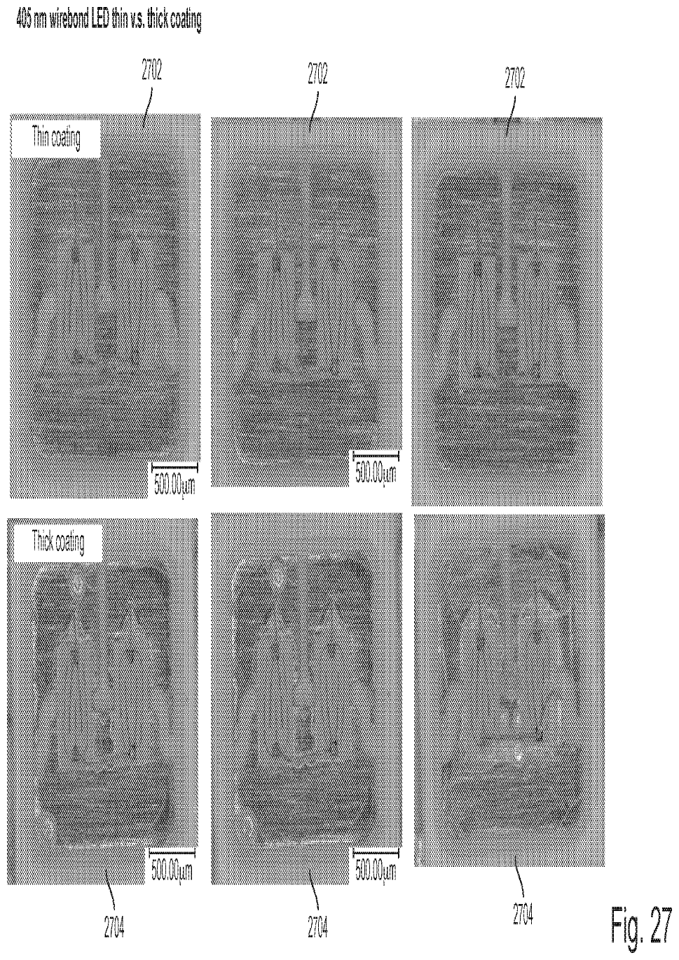

FIG. 27 illustrates microscope images of two families of mid-power packages (2702 and 2704). As can be seen, packages with a thin protective coating, 2702, have no cracks by the end of the deposition process, while the packages with thick coating, 2704, have cracks. Accordingly, FIG. 170 shows that the packages with cracks have worse reliability under high temperature operating life (HTOL) when tested with an LED operated at 85° C. and 120 mA (a current density of about 40 A/cm2). The radiometric output is reduced by about 4% at 2000 hrs. in packages with cracks. Contrary, the packages without cracks have a radiometric output stable within 1% at 2000 hrs. While the data of FIG. 170-27 pertains to wire-bonded dies, similar results hold for other dies, such as flip chip dies.

In various embodiments, a protective coating may have low permeability and also have low elasticity and crack resistance. In such embodiments, the protective coating thickness may be less than 20 microns. In other embodiments, a protective coating may have higher permeability and also have higher elasticity and crack resistance. In such embodiments, the protective coating thickness may be more than 20 microns. These embodiments illustrate that there may be a trade-off between protective coating permeability and probability of protective coating cracking. Thinner protective coatings have a lower probability of cracking, but has higher permeability and provides less protection from atmospheric agents. Some thicker protective coatings have a higher probability of cracking, but has lower permeability that provides better protection from atmospheric agents.

The level of protection against atmospheric gasses provided by the protective coating for the reflective layer can be quantitatively measured by exposing the protective coating-coated package to a sulfur rich environment and observing the light output change of the LED package over time.

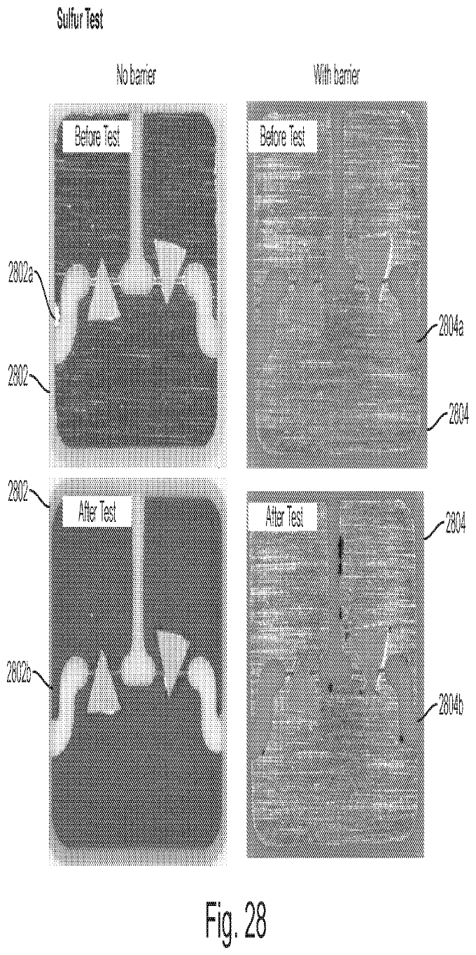

FIG. 28 illustrates two packages 2802 and 2804. Package 2802 does not include a protective coating and package 2804 does include a protective coating. The degradation of the reflective layer(s) of each package was test by exposing both packages to sulfur for 8 hours. 2802a shows package 2802 before exposure and 2802b shows package 2802 after exposure. As can be seen, significant sulfurization of the reflective layer has occurred. Contrary, 2804a shows package 2804 before exposure and 2804b shows package 2804 after exposure, and as can be seen, only very minor spot sulfurization has occurred. Thus, the protective layer of 2804 reduced the effects of the sulfur on the reflective layer of 2804.

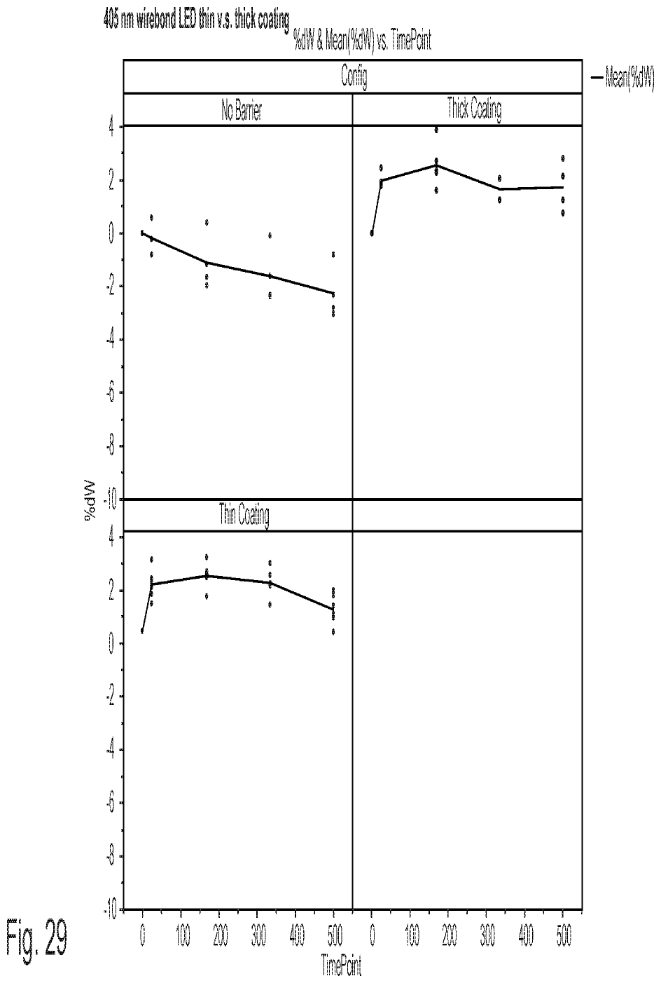

FIG. 29 illustrates a comparison of wet high temperature operating life (WHTOL) reliability for packages with and without a protective coating. The WHTOL test was performed at 120 mA drive current (or a current density of 25 A/cm2) and 60° C. ambient temperature. For packages without a protective coating, a light brown discoloration of the reflective layer develops over time, causing radiometric flux to drop (−2% at 500 hrs). For packages with the protective coating, there no visible change to the reflective layer. This may be characterized by a radiometric flux constant within +/−0.5%, +/−1% or +/−2% at 500 hrs.

In one or more embodiments, the use of surface treatments such as Ar/H2 plasma and chemical or physical etching may improve the protective coating's uniformity, protective coating adhesion and reduce the occurrence of cracking and or delamination. Such treatments may be applied to the reflective layer prior to deposition of the protective coating.

In one or more embodiments, the at least one reflective layer 1706 may be disposed at later stage in the process of producing a package, such as package 1700, to avoid degradation of its reflectivity. For example, the at least one reflective layer 1706 may be deposited by a plating step (such as electroplating), after all the photolithography, printing and molding steps have been performed.

In some embodiments, the protective coating 1708 is formed over the submount 1702 surface and the violet LED die 1704 is then coupled to the submount 1702, over the protective coating. In other embodiments, the violet LED die 1704 is first coupled to the submount 1702 and the protective coating 1708 is then applied. Further, the at least one reflective layer 1706 may be formed on the submount 1702 before the violet LED die 1704 is couple to the submount 1702 or the at least one reflective layer 1706 may be formed on the submount 1702 after the violet LED die 1704 has been coupled to the submount 1702.

FIG. 18 illustrates geometries of the protective coating 1824 according to various embodiments. The protective coating 1708 may cover various parts of the package, including the violet LED die 1822, flat areas of the submount 1820, slanted areas of the submount 1820, the molding compound of the submount 1820, and/or the encapsulant material 1826. In various embodiments, the violet LED die 1822 may be partially or fully covered by protective coating 1824. Further, in one or more embodiments, the protective coating 1824 covers the parts of the package which are most prone to degradation.

1802 of FIG. 18 illustrates an embodiment where the angled area (cup) and flat area (submount surface) of submount 1820 and the sides and top of violet LED die 1822 are covered by protective coating 1824. 1804 illustrates an embodiment where the angled and flat areas of submount 1820 and the top of violet LED die 1822 are covered by protective coating 1824. 1806 illustrates an embodiment where the angled and flat areas of submount 1820, the area beneath violet LED die 1822 and the top of violet LED die 1822 are covered by protective coating 1824. 1808 of FIG. 18 illustrates an embodiment where the angled and flat areas of submount 1820 and the sides and a portion of the top of violet LED die 1822 are covered by protective coating 1824. 1810 illustrates an embodiment where the flat areas of submount 1820 and the sides and top of violet LED die 1822 are covered by protective coating 1824. 1812 of illustrates an embodiment where the angled and flat areas of submount 1820 and the top of violet LED die 1822 are covered by protective coating 1824. 1814 and 1818 illustrate embodiments where the encapsulant is covered by covered by protective coating 1824. 1816 illustrates an embodiment where the encapsulant as well as at least a portion the submount 1820 and at least a portion of violet LED die 1822 is covered by covered by protective coating 1824.

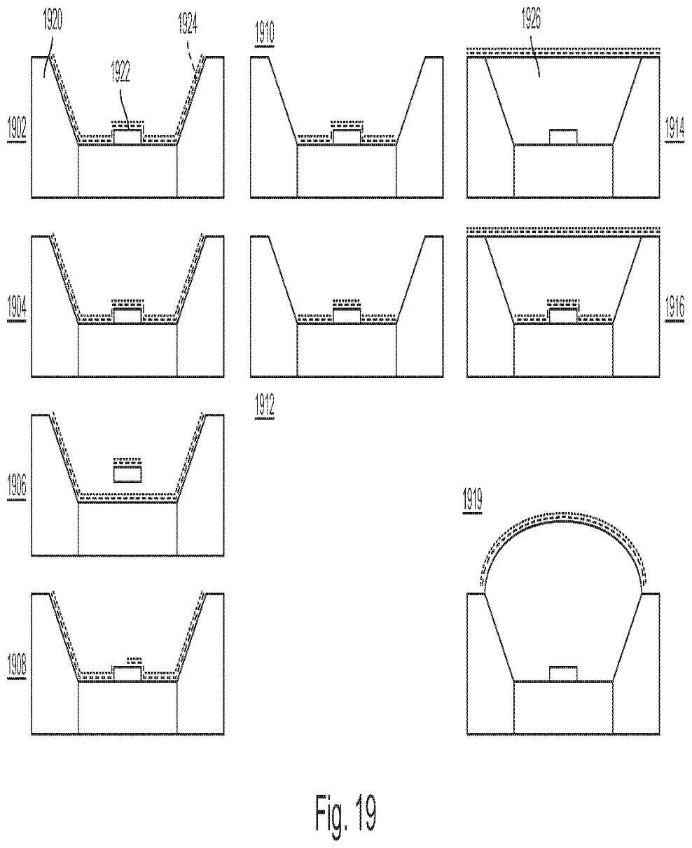

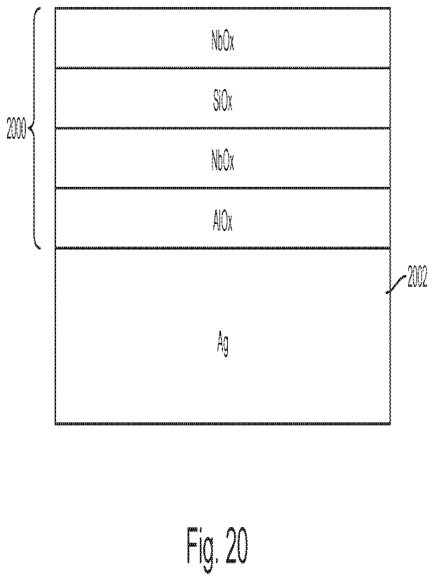

FIG. 19 illustrates various additional geometries of protective coating 1920. As is illustrated in each embodiment of FIG. 19, the protective coating 1920 comprises multiple layers. In various embodiments, more than two materials may be used. The embodiments of FIG. 19 show examples where the layers of the protective coating 1920 cover the same areas of the package; however, other embodiments may also have different coverage for one or more of the layers.

1902 of FIG. 19 illustrates an embodiment where the angled and flat areas of submount 1930 and the sides and top of violet LED die 1922 are covered by protective coating 1924. In such embodiments, the protective coating may be a multi-layer coating which may also have reflective properties. 1904 illustrates an embodiment where the angled and flat areas of submount 1930 and the top of violet LED die 1922 are covered by protective coating 1924. 1906 illustrates an embodiment where the angled and flat areas of submount 1930, the area beneath violet LED die 1922 and the top of violet LED die 1922 are covered by protective coating 1924. 1908 illustrates an embodiment where the angled and flat areas of submount 1930 and the sides and a portion of the top of violet LED die 1922 are covered by protective coating 1924. 1910 illustrates an embodiment where the flat areas of submount 1930 and the sides and top of violet LED die 1922 are covered by protective coating 1924. 1912 illustrates an embodiment where the angled and flat areas of submount 1930 and the top of violet LED die 1922 are covered by protective coating 1924. 1914 and 1918 illustrate an embodiment where an encapsulant 1926 is covered by covered by protective coating 1924. 1916 illustrates an embodiment where the encapsulant 1926 as well as at least a portion the submount 1930 and at least a portion of violet LED die 1922 are covered by protective coating 1924.

FIG. 23 shows a graph 700 of the radiometric degradation of two types of LED packages having violet LEDs. A first one of the packages has no protective coating over the reflective layer and a second one of the packages has a protective coating over at least a portion of the reflective layer. 2302 corresponds to the radiometric degradation of a LED package lacking a protective coating over the reflective layer and 2304 corresponds to the radiometric degradation of an LED package having a protective coating over the reflective layer. The latter package has a protective coating and shows much smaller degradation. The percent change in radiometric output for 2302 is greater than that of 2304, where the radiometric degradation is less than 5% at 500 hrs of operation. Thus, it can be concluded that the protecting coating reduces output degradation of the one or more reflective layers.

In various embodiments, various test conditions for determining the extent of degradation may be considered. For example, one or more of the temperature, LED current, LED current density and testing time may be varied for testing. In various embodiments, the temperature may be 25° C., 85° C., or 130° C. The LED current may be 10 mA, 50 mA, 100 mA, 120 mA, or 200 mA. The LED current density may be 10 A/cm2, 20 A/cm2, 50 A/cm2, 100 A/cm2, 200 A/cm2, 500 A/cm2, or 1000 A/cm2. The testing time may be 100 hrs, 200 hrs, 500 hrs, 1000 hrs, 5000 hrs, or 10000 hrs. In one or more embodiments, the test conditions include the introduction of an additional factor which can induce degradation, including water vapor or sulfur.

For a selected set of test conditions, one or more parameters of the protective coating may be configured to achieve a predetermined radiometric maintenance. For example, the type of material or materials, number of layers and the placement of the protective coating may be selected to configure the protective coating to achieve a predetermined radiometric maintenance.

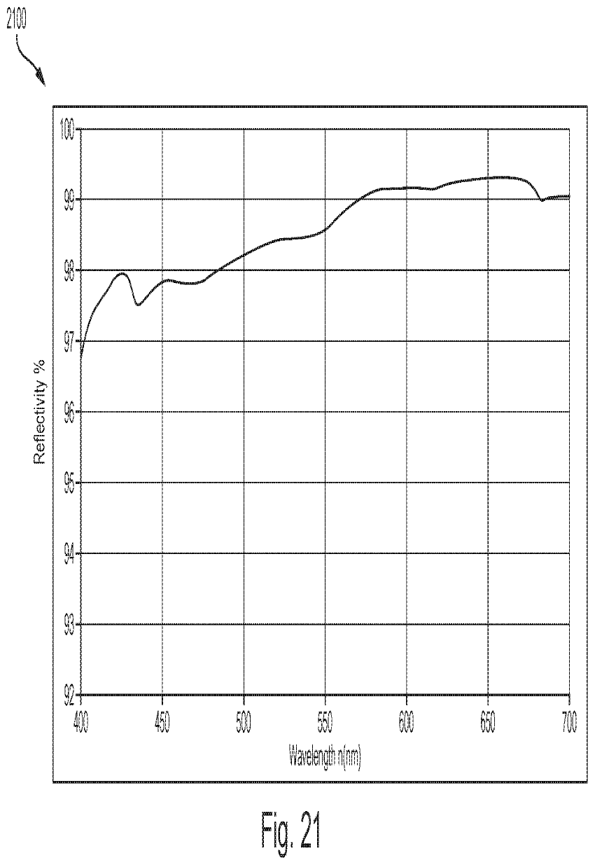

In the embodiment of FIG. 20, an example of a multilayer protective coating 2000 applied to a silver, Ag, surface 2002 is illustrated. As is illustrated, the coating 2000 comprises four layers: AlOx, Nbx, SiOx, NbOx. All the materials may have a beneficial role for degradation (by acting as protective coatings or barriers). In addition, the thickness and refractive index of each material may be configured to increase reflectivity. For example, in one specific example he following layer thicknesses may be employed: a layer of AlOx at 58 nm, a layer of NbOx at 62 nm, a layer of SiOx at 192 nm, and a layer of NbOx at 60 nm. This follows known methods for configuring dichroic mirrors, for instance by having layers whose thickness is on the order of lambda/4n, with lambda a design wavelength (typically in a range 400-700 nm) and n the refractive index of the material in question. In one or more embodiments, the protective coating 2000 may then be encapsulated with a standard silicone of index 1.45.

FIG. 21 shows a graph, graph 500, of the corresponding reflectivity, averaged over all directions of incidence with a Lambertian distribution (i.e. the reflectivity is integrated with a cos(theta) term corresponding to the Lambertian photon distribution, and with a sin(theta) term corresponding to the solid angle distribution). As is illustrated, the reflectivity is above 97% in the range of about 400 nm-about 700 nm, and above 98% in the range of about 500-about 700 nm.

In various embodiment, more complex configuration may be employed, as is known in the art, to reach even higher reflectivity. Some embodiments may have tens of layers, and may be designed as distributed Bragg reflectors. Optimization of the reflectivity may be obtained by techniques described within this disclosure. In particular, the stack may be configured to provide high reflectivity in the presence of an underlying silver reflector.

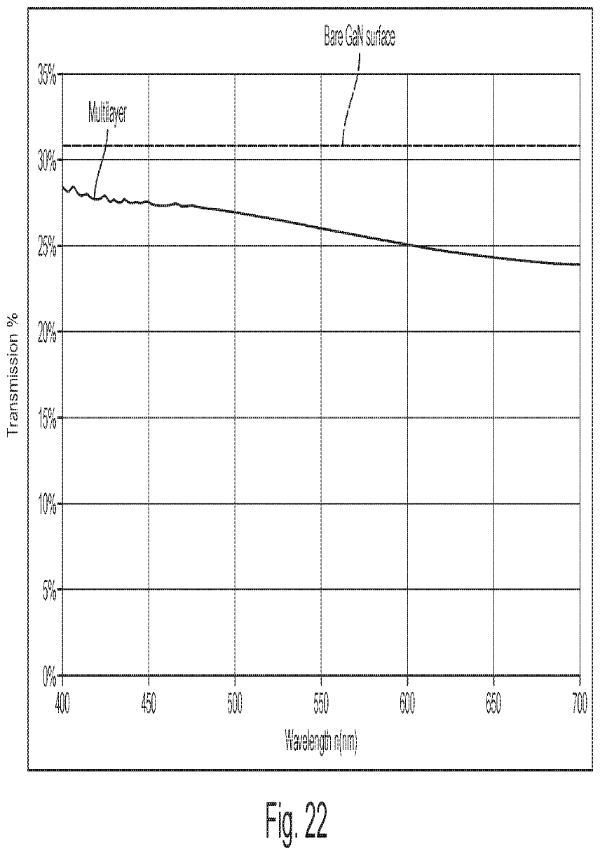

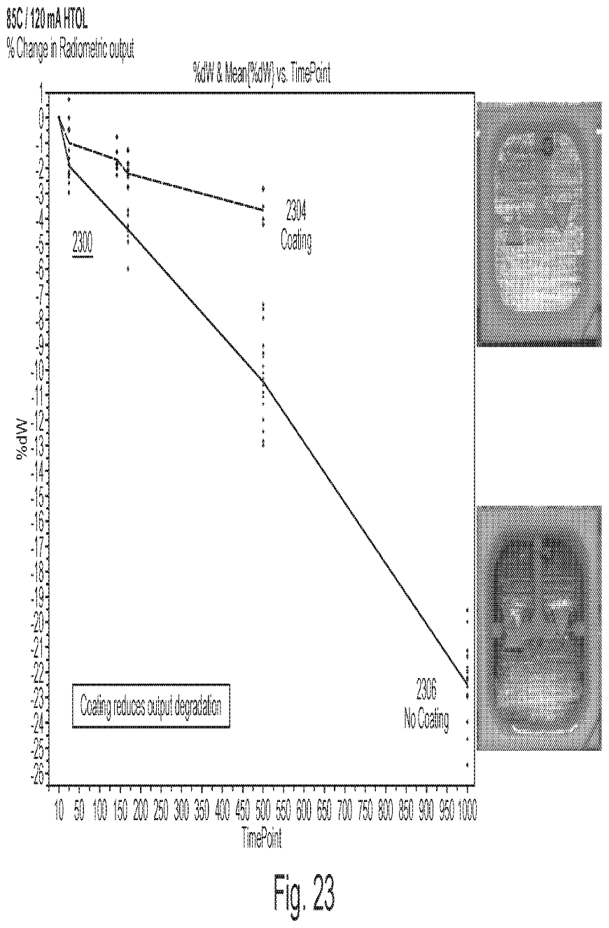

FIG. 22 illustrates graph 600 showing the calculated transmission for light coming from an LED die comprising a GaN substrate, going through the same multilayer coating as on FIG. 21 (AlOx, NbOx, SiOx, NbOx) and escaping to silicone. The LED die was coated with a protective coating and the protective coating is configured to achieve a high transmission for the light emitted by the LED die. The transmission is averaged over all angles of incidence, as explained above. It is therefore smaller than unity, because a lot of the light undergoes total internal reflection due to the high index of GaN. Nonetheless, FIG. 22 shows that the net transmission is similar for an uncoated GaN/silicone interface (31%) and for the interface with the coating (27% in the wavelength range of about 400 nm-about 450 nm, corresponding to common LED dies).

In some embodiments, the multilayer coating disposed over a violet LED die has a normal-incidence transmission which is higher than 80% (or 90%, or 95%, or 97%, or 99%) at the LED's peak emission wavelength.

In some embodiments, the protective coating has an angle-averaged transmission (as explained above) which is higher than 20% (or 25%, 30%, 35%) at the LED's peak emission wavelength.

In some cases, use of more than one material to for a protective coating improves the degradation properties, as each material may have a specific beneficial effect (for instance, each material is a diffusion barrier for some chemical species).

In some embodiments, the protective coating comprises a plurality of layers having varying refractive index. In such embodiments, the protective coating may be configured to provide additional reflectivity for light. For instance, the protective coating may be configured to create an interference effect in the presence of the underlying reflective layer or layers, to increase the reflectivity.

In one or more embodiments, the protective coating comprises at least one low-index layer having an index less than about 1.55 or 1.5. For example, the protective coating may comprise a nano-porous material having an index of refraction less than about 1.4, 1.3 or 1.2. In one embodiment, the protective coating comprises at least one high-index layer having an index more than about 1.6, 1.7, 1.8, 1.9, 2, 2.1, 2.2, 2.3, 2.4, or 2.5.

In particular, in some embodiments, the coating covers both the reflective surface and the die (or part thereof). The coating is configured to be substantially transparent for light emitted from the LED; but to produce an interference effect with the reflective metal to enhance its reflectivity.

### Exemplary Embodiments

It should be understood that the features of the embodiments above can be mixed and match to provide novel LED packages. While the existence of some of these aspects might be known in the prior art, their combination may provide unexpected benefits over common practice in the prior art. For example, the features described above may be combined as follows:
Short-wavelength die with a silver reflector and a protective layer for silver (no phenyl silicone). This may enable a reliable combination of Ag reflector and short-wavelength, without Ag tarnish.
Short-wavelength die with a package having a non-conductive reflector (including a white reflector or a dichroic) and substantially no exposed metal. This may enable reliable operation with short-wavelength die, without resorting to silver.
Package having a volumetric die (possibly a short-wavelength die) and a non-conductive reflective surface which does not substantially protrude over the lateral sides of the die. This may enable high-performance and reliability.
Flip-chip die attached to a mid-power package having a ceramic substrate. This may enable reliable die-attach and operation without thermal expansion issue.
Small flip-chip die having a Sn-based die-attach metallization (potentially attached to a package whose metal contacts are thicker than a certain thickness). This may enable reliable die-attach and operation of a flip-chip die on a package having some thermal expansion mismatch.
Design of packages with small gaps between electrodes to accommodate small flip-chip dies (including photolithography-based electrode definition rather than wat etching).
Fabrication process for a package combining a dual-layer metal on ceramic and a reflective white material (which potentially covers most or all of the metallization). This may enable an efficient electrical contact scheme while maximizing reflectivity.
Fabrication process comprising a ceramic-based substrate tile, a tile-level phosphor dispense, a singulation step and reflector formation to obtain top-emitting or side-fire packages with parallel processing.

Performance and Reliability

In some embodiments, the invention is configured for high performance including high optical performance and high optical performance at short wavelength. As is known in the art, performance may be measured as white wall plug efficiency, or lumens per watts, at a given current (or current density in the active region) and at a given temperature; performance may also be expressed as package efficiency.

In some embodiments, as previously described, the phosphor is contained within a cup. The package cups can be round, square, rectangular and elliptical in the light emitting area, depending on the number of dies used, the shapes of the dies used, and the packaging method (wirebond or flip-chip).

In some embodiments, the package cup height can range from 0.2-0.5 mm for good performance and compatibility with packages processes.

The lateral dimensions of the cup may influence performance. Namely, as the light-emitting area (i.e. the area of the top surface of the phosphor) shrinks, the cup tends to absorb more light. On the other hand, it may be desirable to shrink the light-emitting area for other reasons (including brightness and color uniformity, as discussed below). Some embodiments are optimized to mitigate the performance drop.

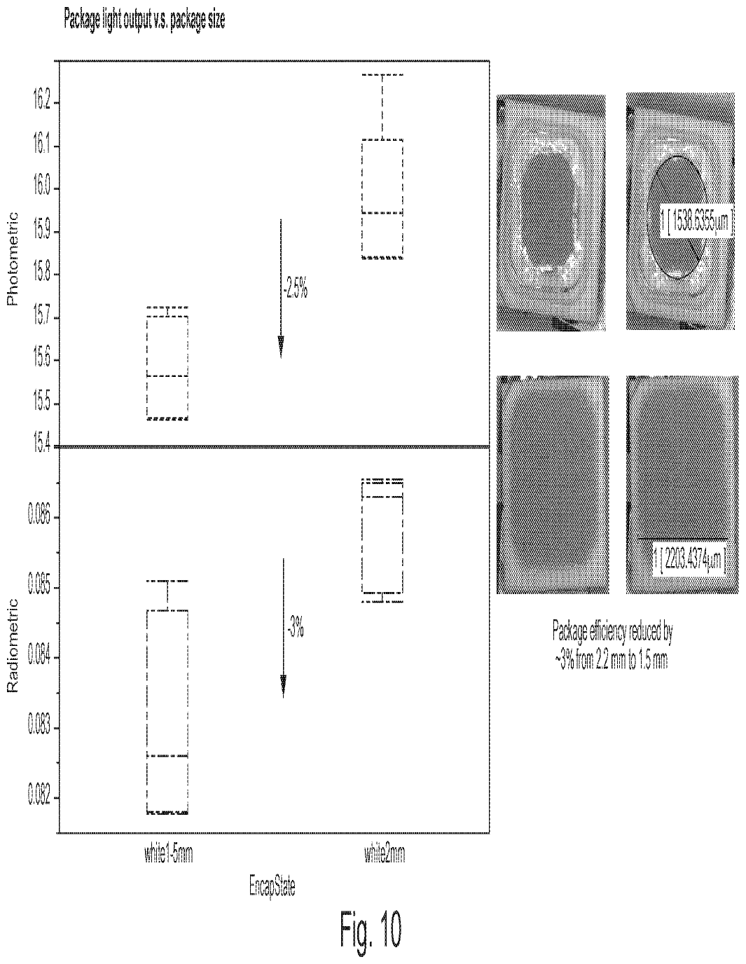

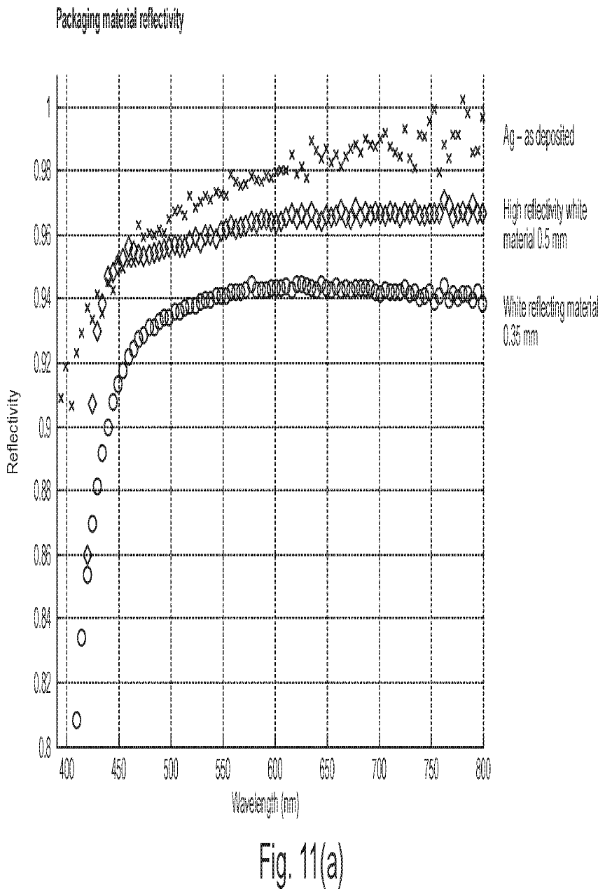

FIG. 10 illustrates this. In FIG. 10, two white-emitting packages are built with light-emitting areas having lateral dimensions of about 2.2 mm and 1.5 mm. Through a suitable choice of high-reflectivity materials (including the material of the cup), the performance drop with the smaller area is limited to only −2.5% (photometric)/−3% (radiometric).

In some embodiments, the package emits substantially white light with the following properties:
CCT=277K, 3000K, 3500K, 4000K, 5000K, 6500K or within a range 2500-6500K
Chromaticity within +/−0.01 points of Planckian (calculated with 1931 2° CMFs or 1964 10° CMFs)
CRI above 80 or 90 or 95
R9 above 0 or 80 or 90 or 95
light-emitting area below 3×3 mm\hat{ }2 (or 2.5×2.5, 2×2, 1.5×1.5, 1.3×1.3, 1×1, 0.8×0.8, 0.5×0.5 mm\hat{ }2).

In some embodiments, for some of the properties above, the package is characterized by some of the following performance:
package efficiency of at least 65%, 70%, 75%, 80%, 85%
radiometric efficiency of at least 24%, 27%, 30%, 33%, 36%, 40%, 45% W/W (optical watts of substantially white light over electrical watts). Radiometric efficiency above 30% has been demonstrated in packages having an Ag reflector with SMC molded cups. When the packages are fully encapsulated, the barrier coating thickness is typically >1 um, which has been shown to not affect the output efficiency.
photometric efficiency above 90 lm/W (or 100, 110, 120 lm/W) at a CRI above 80 or above 75 lm/W (or 60, 85, 95, 105 lm/W) at a CRI above 90.

| | | | | | | | | Current | | |
|---|---|---|---|---|---|---|---|---|---|---|
| Reflector | Cup | | CCT | | | | | density | | Wopt/ |
| type | Type | LEA | (K) | CRI | PE | Temperature | Current | (A · cm-2) | lm/W | Welec |
| Ag | High R | 1.3 × | 2700 | 86 | 69% | 95 C. | 55 | 110 | 61.1 | 29.4% |
| | | 1.3 mm | | | | | | | | |
| Ag | High R | 1.3 × | 2700 | 86 | 69% | 95 C. | 80 | 160 | 57.3 | 27.5% |
| | | 1.3 mm | | | | | | | | |
| Ag | Mid R | 1.3 × | 2700 | 86 | 67% | 95 C. | 55 | 110 | 59.7 | 28.7% |
| | | 1.3 mm | | | | | | | | |
| Ag | Mid R | 1.3 × | 2700 | 86 | 67% | 95 C. | 80 | 160 | 56 | 26.9% |
| | | 1.3 mm | | | | | | | | |
| Ag | Mid R | 2.2 × | 2700 | 86 | 72% | 95 C. | 55 | 110 | 63.7 | 30.6% |
| | | 2.2 mm | | | | | | | | |
| Ag | Mid R | 2.2 × | 2700 | 86 | 72% | 95 C. | 80 | 160 | 59.7 | 28.7% |
| | | 2.2 mm | | | | | | | | |
| Ag | Mid R | 2.2 × | 2700 | 75 | 75% | 80 C. | 120 | 240 | 59.9 | 23.7% |
| | | 2.2 mm | | | | | | | | |

Some experimental results are listed in the table below.

The cup is a white diffusing material, and can be high-reflectivity or medium-reflectivity material. It should be appreciated that the lm/W numbers may be affected by the shape of the spectrum (namely, various of these experiments correspond to spectra with high violet leaks, which have a low luminous equivalent of radiation).

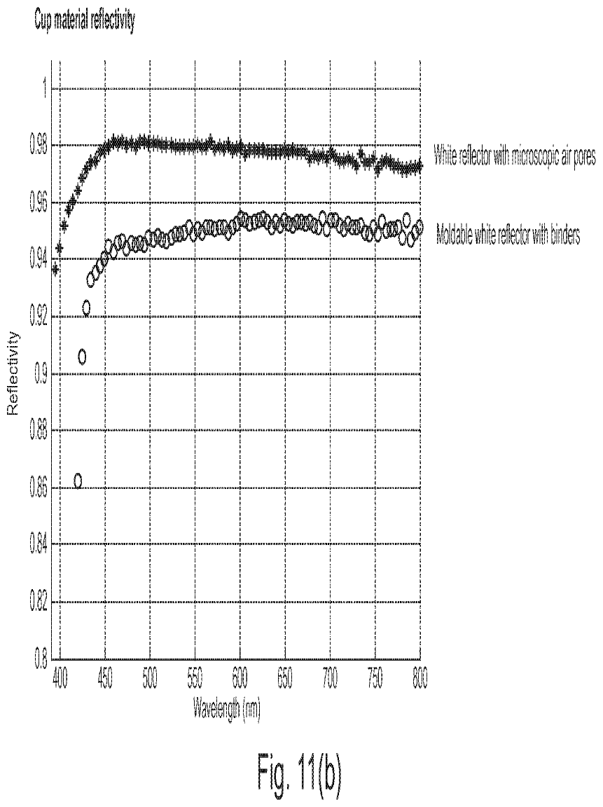

In the case of exposed silver, the reflectivity may correspond to that shown for Ag on FIG. 11(a). Most critically for Ag, the reflectivity spectrum curvature at wavelengths below 450 nm may be important. In some embodiments, the Ag reflectivity at 400 nm is at least 90% (or 80%, 85%, 92%, 94%). The silver may be deposited by one of the following techniques: electroplating, electro-less plating, sputtering, electron beam deposition, thermal evaporation.

In some embodiments, the surface of the package (before deposition of the phosphor material) is partially or fully covered by a white reflecting material. The reflectivity of the material depends on the material composition, thickness and fabrication technique. High reflectivity white material that are sufficiently thick can reach reflectivity >96%. Medium reflectivity material that are sufficiently thick can reach reflectivity >93%.

FIG. 11 shows examples of white reflecting materials and illustrates the effect of thickness. In some embodiments the reflectivity is above 85% or 90% in the wavelength range 450-700 nm. FIG. 11 pertains to common white reflecting materials, comprising a mix of a silicone-based binder and diffusing particles. These materials are usually designed for providing high reflectivity with a thickness of hundreds of microns.

On the other hand, it is also possible to configure white materials having a high reflectivity with a lower thickness. This may be achieved by configuring the scattering particle size (for instance, by having a plurality of particle sizes to scatter several wavelengths of light efficiently and increase packing of the scattering particles in the binder). Besides, it is possible to lay down a thin layer of such materials on a thick “gray” substrate (i.e. an imperfectly-reflecting substrate such as some ceramics). With the right combination of substrate type and thickness, and white material type and thickness, high reflectivity can be achieved despite a modest thickness of white material.

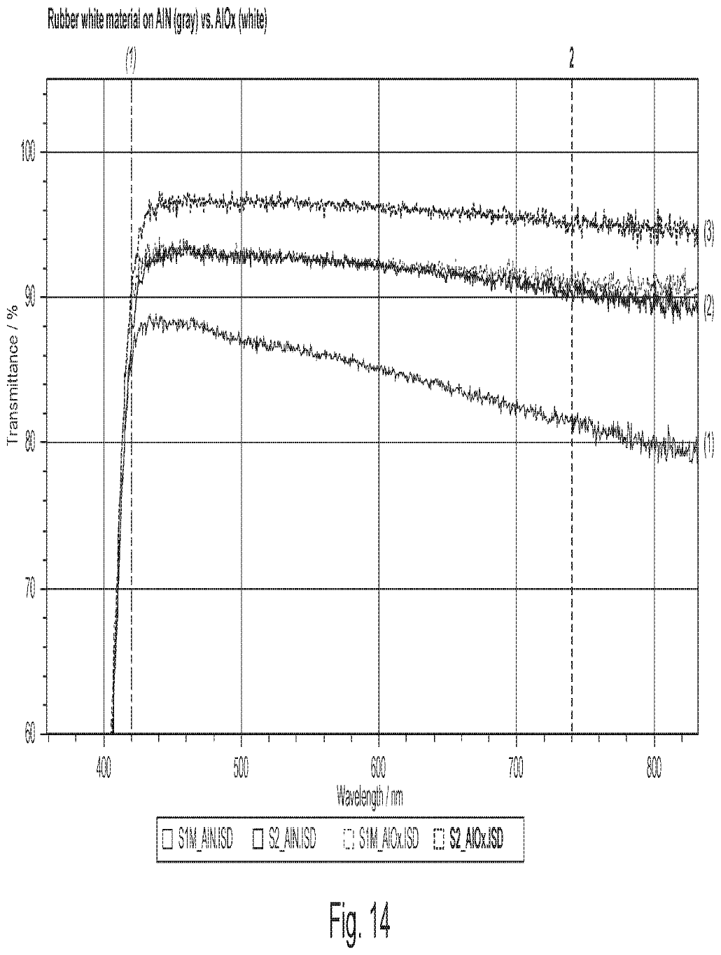

FIG. 14 exemplifies such embodiments and shows the reflectivity of such stacks of white material on ceramic substrates. Line (1) corresponds to a 20 um thick white layer on an AlN substrate. Despite the very thin layer, reflectivity remains above 80% in the range 420 nm-700 nm with a peak reflectivity 88%. Line (2) corresponds to a 40 um thick white material on AlN. Here the reflectivity is above 90% in the range 420-700 nm and peaks at 94%. Finally, line (3) corresponds to 40 um white material on an AlOx substrate. The substrate itself is more reflective. The stack has a reflectivity above 94% in the wavelength range 420-700 nm peaking at 97%.

Note that the measurements of FIG. 15 correspond to true reflectivity (i.e. transmitted light leaking through the substrate is not collected).

In some embodiments, the substrate is translucent. To recuperate the light that leaks through the substrate, a reflector may be placed on the backside of the substrate to reflect the light back upwards. The reflector may be a white reflector or a metal.

In various embodiments, the substrate material, and the white material and its thickness, are configured to reach a desired reflectivity in a desired wavelength range.

For all the white reflectivities measured in this application, data is collected coming from air. It is important to realize that reflectivity improves when the incoming medium is a high-index encapsulant like silicone (n˜1.4-1.6). This is because scattered light trajectories have a higher chance of re-entering silicone than air. The ratio of “escape cone” solid angles is about n\hat{ }2/1\hat{ }2˜2, therefore it is about double. Thus the loss when coming from silicone to air is about halved. This has been verified in careful experiments with light coming from a high-index medium. Accordingly, the table below translates reflectivities in air to equivalent reflectivities in a high-index medium:

| R in | R in |
|---|---|
| air | encapsulant |
| 50% | 75% |
| 60% | 80% |
| 70% | 85% |
| 80% | 90% |
| 85% | 93% |
| 90% | 95% |
| 92% | 96% |
| 94% | 97% |
| 96% | 98% |
| 98% | 99% |

The material used in FIG. 15 has a cutoff around 420 nm. However, different materials can push this cutoff to shorter wavelength. For instance a white reflector using anatase-phase TiO2 particles will have a shorter-wavelength cutoff than a material using rutile-phase TiO2 particles.

As previously mentioned, some embodiments comprise a cup. The cup may be made highly reflective, with reflectivity >95% at 550 nm for reflectors using silicone binders suitable for dispensing and molding, or >98% at 550 nm for reflectors with microscope air pores or filaments that are manufactured separately from the package but later combined using lamination or adhesives.

FIG. 11(b) illustrates the reflectivity of such cup materials. In some embodiments the reflectivity is above 90%, 94% or 96% in the wavelength range 450-700 nm.

In some embodiments, the surface coverage of the package is configured to offer high performance. Some examples are shown on the table below. Some examples correspond to configurations with exposed Ag (either “maximal” Ag or “minimal” Ag), others have no exposed Ag and only a white reflector. In this table, the area coverage refers to the “open” package area where no dies are present and light can impinge on the package.

| | | | | | Reflectivity 2 | |
|---|---|---|---|---|---|---|
| | | Reflectivity | | | at all | |
| | Material | 1 | Area 1 | Material | wavelengths | Area 2 |
| # | 1 | at 400 nm | coverage | 2 | 450-700 nm | coverage |
| 1 | Ag | >85% | >75% | White | >85% | <25% |
| 2 | Ag | >90% | >75% | White | >85% | <25% |
| 3 | Ag | >85% | >90% | White | >85% | <10% |
| 4 | Ag | >90% | >90% | White | >85% | <10% |
| 5 | Ag | >85% | >75% | White | >90% | <25% |
| 6 | Ag | >90% | >75% | White | >90% | <25% |
| 7 | Ag | >85% | >90% | White | >90% | <10% |
| 8 | Ag | >90% | >90% | White | >90% | <10% |
| 9 | Ag | >70% | <20% | White | >90% | >80% |
| 10 | Ag | >90% | <20% | White | >90% | >80% |
| 11 | — | | | White | >85% | ~100% |
| 12 | — | | | White | >90% | ~100% |

Color uniformity: In other embodiments, performance is measured by color-over-angle in the far-field of the package, or as color-versus-position in the near-field of the package.

For applications in directional lighting, the light emitting area of the light source directly impacts the achievable center beam candle power of lenses with a fixed size. For this reason, the package must be sized appropriately taking into account both the light emitting area, as well as its impact on the efficiency of the package. In general, smaller light emitting area both constrains the LED die size that can be used, and also reduces the overall efficiency of the package due to increase light scattering and smaller aperture for light to escape the package.

In some embodiments, the phosphor powder within the encapsulant is allowed to sediment during the dispense process to improve package color over angle. In some embodiments, the phosphor silicone mixture is sprayed on to the package to improve color over angle

The color uniformity versus position on the package is critical for directional lighting purposes because it has a strong effect on the product color-over-angle in the far field. In order to reduce the color variation as a function of position in the package, the following design rules may be beneficial
Design a total light emitting area which is not too much larger than the total LED die area
If multiple LED dies are used in a single package, spread them out in such a way that the die to die distance is similar to the die-to-cup distance.

In some embodiments, the size of the light-emitting area and the size and position of the pump dies is configured to obtain a near-field uniformity below a predetermined value.

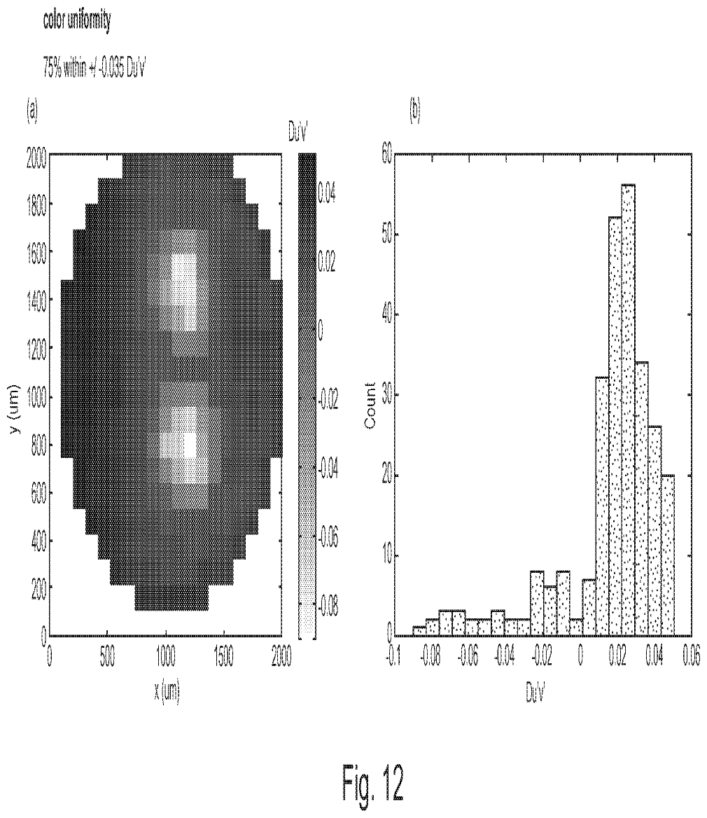

FIG. 12 shows an example of a package's color uniformity. In this experiment, a package (with two violet dies and a phosphor material, in a package with a circular aperture 2 mm in diameter) is fabricated then its near-field spectrum is measured. The average chromaticity (u′0, v′0) of the emitted light is computed, and the local chromaticity difference at each position Du′v′ is computed as:

Du′v′=sqrt((u′−u′0)2+(v′−v′0)2)*sign(v′−v′0)

This local chromaticity is shown on FIG. 12a (data is only shown in the light-emitting are of the package). The corresponding frequency histogram is shown on FIG. 12b. For this configuration, uniformity is moderate. 75% of the package's light-emitting area is within values Du′v′ of +/−0.035. This lack of uniformity can be traced to the very large area of the light-emitting area against the die area.

FIG. 12 shows another package, where the dimensions and shape of the package and the die positions have been adapted to improve color uniformity: the light-emitting area is now rectangular with a smaller aperture ˜1.6*2 mm. Figs. K8 a and b show the same data as above. In this case, 75% of the package's light-emitting area is within values Du′v′ of +/−0.016: a significant improvement in uniformity.

In some embodiments, the package size/dimensions/shape, the layout of the dies, and the phosphor (formulation, height etc) are configured such that 75% of the package's light-emitting area is within values Du′v′ lower than +/−0.020 (or 0.015, 0.010).

Reliability

Sulfur: In some embodiments, the package is resistant to sulfur atmosphere.

In sulfur tests, the package is introduced in an enclosed sulfur atmosphere and maintained at a temperature of 65 C, without electrical injection. Reliability is assessed by degradation of the package materials or by loss in optical output.

After a predetermined exposure time of 8 hrs (or 12, 24, 48, 72 hrs), the fraction of the package surface area which is optically degraded may be below 1% (or 0.1%, 2%, 5%, 10%). In general, optical degradation may be defined by direct visual observation; or by a local reduction in reflectivity by a predetermined amount (for instance, an absolute reflectivity decrease worse than −5%, −10% or −20% at a selected wavelength such as 400 nm, 500 nm, 600 nm); or by measuring the reduction in light output (less than −1%, −2%, −5%, −10%). Such sulfur tests may be performed either in the absence or presence of a phosphor material.

HTOL: In some embodiments, the package is reliable in High-temperature Operating Life testing.

In HTOL, the package is electrically injected at high temperature in a dry atmosphere. The test time may be 500 hrs, 1,000 hrs, 5,000 hrs, 10,000 hrs. The package temperature may be 65 C, 80 C, 100 C, 120 C, 150 C, 200 C. The current density in the LEDs may be 20 A·cm−2, 40 A·cm−2, 60 A·cm−2, 80 A·cm−2, 100 A·cm−2, 150 A·cm−2, 200 A·cm−2, 300 A·cm−2, 500 A·cm−2.

Reliability is assessed by loss in optical output, or by damage to the package including optical tarnish, browning, delamination, cracking, or by electrical leakage. Embodiments are given in the table below:

| | | | LOP |
|---|---|---|---|
| T | J | time | drop less |
| (c) | (A · cm−2) | (hrs) | than |
| 85 | 240 | 500 | −0.50% |
| 85 | 240 | 1000 | −1% |
| 85 | 240 | 5000 | −2% |
| 85 | 30 | 500 | −0.50% |
| 85 | 30 | 1000 | −1% |
| 85 | 30 | 5000 | −2% |
| 120 | 240 | 500 | −1% |
| 120 | 240 | 1000 | −2% |
| 120 | 240 | 5000 | −4% |

WHTOL: In some embodiments, the package is reliable in Wet High-temperature Operating Life testing.

In WHTOL, the package is electrically injected at high temperature in a wet atmosphere (for instance, above 80% humidity). The test time may be 100 hrs, 200 hrs, 500 hrs. The package temperature may be 60 C, 80 C, 100 C, 120 C. The current density in the LEDs may be 20 A·cm−2, 40 A·cm−2, 60 A·cm−2, 80 A·cm−2, 100 A·cm−2, 150 A·cm−2, 200 A·cm−2, 300 A·cm−2, 500 A·cm−2. The power cycle may be: on at all times, or switching on-off with a predetermined duty factor (including 25%, 50%, 75%) and a predetermined period (including 30 min, 1 hr, 2 hrs).

In some embodiments, reliability is assessed by loss in optical output, or by damage to the package including optical tarnish, browning, delamination, cracking, or by electrical leakage. Embodiments are given in the table below:

| | | | LOP | Voltage |
|---|---|---|---|---|
| | | | drop | drop |
| T | J | time | less | less |
| (c) | (A · cm−2) | (hrs) | than | than |
| 60 | 240 | 100 | −0.50% | −2% |
| 60 | 240 | 200 | −1% | −5% |
| 60 | 240 | 500 | −2% | −10% |
| 60 | 30 | 100 | −0.50% | −2% |
| 60 | 30 | 200 | −1% | −5% |
| 60 | 30 | 500 | −2% | −10% |

These and other advantages maybe realized in accordance with the specific embodiments described as well as other variations. It is to be understood that the above description is intended to be illustrative, and not restrictive. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled.

1. An LED package comprising:
a submount comprising a substrate, at least one electrical interface, and a non-conductive reflective material disposed over substantially all of the substrate except for said at least one electrical interface; and
at least one LED chip having at least one contact, said LED chip being flip-chip mounted to said submount such that said at least one contact is electrically connected to said at least one electrical interface, said LED chip covering a substantial portion of said at least one electrical interface, substantially all of said chip extending above said reflective material.

2. The LED package of claim 1, wherein said reflector material has a top surface

3. The LED package of claim 2, wherein at least 90% of the area of lateral sides of said LED chip is above said top surface.

4. The LED package of claim 2, wherein all of said LED chip is above said top surface.

5. The LED package of claim 2, wherein said top surface is substantially coplanar with the top of said pad.

6. The LED package of claim 1, wherein said reflective material comprises a white reflecting material or a dichroic reflector.

7. The LED package of claim 2, wherein said the submount is configured such that the top surface has a reflectivity of at least 90% at all wavelengths in the range 400-700 nm.

8. The LED package of claim 1, further comprising a die attach stack between said contact and said electrical interface.

9. The LED package of claim 8, wherein said die attached stack is a metallic stack comprising a Sn layer having a thickness of at least about 2, 5, 10, 20, or 50 um, or in the range 2-50 um or 5-20 um.

10. The LED package of claim 1, wherein said substrate is substantially made of a ceramic.

11. The LED package of claim 1, wherein said substantially all is at least 90%.

12. The LED package of claim 1, wherein said substantial portion is at least 90%.

13. The LED package of claim 1, wherein said LED chip is configured to emit at a peak wavelength shorter than 430 nm.

14. The LED package of claim 13, further comprising an encapsulant disposed over said LED chip and said submount, said encapsulant having an absorption less than 0.1 cm−1 at said peak wavelength.

15. The LED package of claim 1, wherein said LED chip is volumetric.

16. The LED package of claim 1, further comprising a reflective cup extending upward from said reflective material on at least one side of the package.

17. The LED package of claim 16, wherein the reflective cup is formed on all lateral sides of the package and light is emitted from a top side of the package.

18. The LED package of claim 16, further comprising a reflective top side such that light is emitted from at least a lateral side of the package.

19. The LED package of claim 1, wherein each of the at least one LED chip comprises two contacts in a flip-chip configuration, and wherein each contact is electrically connected to an electrical interface of the submount.

20. The LED package of claim 1, wherein the LED emits a pump light and least 20% of the pump light is emitted from the lateral sides of the LED.

21-80. (canceled)
